(19) United States
(12) Patent Application Publication
(10) Pub. No.: US 2017/0261559 A1
(43) Pub. Date: Sep. 14, 2017

(54) METHOD FOR QUANTITATIVE EVALUATION OF SWITCHED RELUCTANCE MOTOR SYSTEM RELIABILITY THROUGH THREE-LEVEL MARKOV MODEL

(71) Applicant: CHINA UNIVERSITY OF MINING AND TECHNOLOGY, Xuzhou, Jiangsu (CN)

(72) Inventors: Hao CHEN, Xuzhou, Jiangsu (CN); Shuai XU, Xuzhou, Jiangsu (CN); Jinlong DONG, Xuzhou, Jiangsu (CN); Xing WANG, Xuzhou, Jiangsu (CN)

(21) Appl. No.: 15/300,660

(22) PCT Filed: Dec. 28, 2015
(86) PCT No.: PCT/CN2015/099103

§ 371 Date: Sep. 29, 2016

(30) Foreign Application Priority Data
Sep. 11, 2015 (CN) 201510580357.6

(51) Int. Cl. G01R 31/34; G06N 7/00

(52) U.S. Cl. CPC G01R 31/34; G06N 7/005

(57) ABSTRACT

A method for evaluation of switched reluctance motor system reliability through quantitative analysis of a three-level Markov model. Through analysis of the operating condition of switched reluctance motor drive system under first-level faults, second-level faults and third-level faults, 4 valid states and 1 invalid state under first-level faults, 14 valid states and 4 invalid states under second-level faults, and 43 valid states and 14 invalid states under third-level faults are obtained. If initial normal state and final invalid state are also considered, a three-level Markov model will have 62 valid states and 20 invalid states in total. A state transition diagram of the switched reluctance motor drive system under three-level faults is established, a state transition matrix is obtained, a probability matrix of the system in valid states is attained, the sum of all elements of the probability matrix is calculated, and MTTF is obtained from a reliability function.

### PRIORITY CLAIM

The present application is a National Phase entry of PCT Application No. PCT/CN2015/099103, filed Dec. 28, 2015, which claims priority to Chinese Patent Application No. 201510580357.6, filed Sep. 11, 2015, the disclosures of which are hereby incorporated by reference herein in their entirety.

### FIELD OF THE INVENTION

The present invention relates to a quantitative evaluation method and is particularly applicable to a method for quantitative evaluation of the reliability of various types of switched reluctance motor systems with multiple phases through three-level Markov model.

### BACKGROUND OF THE INVENTION

The quantitative analysis of reliably mainly includes two parts: establishment of a reliability model and quantitative solving based on the reliability model. A conventional reliability modeling method can express only two states of switched reluctance motor system: basically normal and invalid, and is unable to represent all operating states of the switched reluctance motor system in the full operation cycle. Although dynamic fault tree and Markov model can represent all possible states of the system, the modeling process of dynamic fault tree needs complex theoretical analysis, not conducive to subsequent quantitative resolving. Currently, popular Markov modeling methods are mostly used in reliability evaluation of software and electronic devices, and the established models do not give play to the excellent features of Markov based on state transition. In general, one fault is one Markov space state, increasing complexity of solving; meanwhile they do not analyze the operating condition of the system under multi-level faults and cannot completely evaluate the reliability and fault tolerance of the system. The methods for quantitative solving through a reliability model mainly include Boolean logic method, Bayes method and Markov state-space method. Boolean logic method and Bayes method cannot meet the analysis requirements under the circumstances of multiple components and multiple faults, while although a conventional Markov state-space method can solve the above problem, the solving time is too long due to influence of space-state quantity and cannot meet the requirement for fast reliability modeling. Therefore, it is urgent to realize classified and quantitative reliability evaluation of switched reluctance motor system through Markov model, which takes into account that a fault may enter different Markov states and can express the state of effective operation of switched reluctance motor system with a fault between a normal state and an invalid state, reduce Markov space-state quantity and rapidly realize quantitative evaluation of switched reluctance motor system reliability.

### SUMMARY OF THE INVENTION

The object of the present invention is to overcome the shortcomings of prior art, and provide a simple, fast and widely applicable method for evaluation of switched reluctance motor system reliability through three-level Markov model.

In order to realize the foregoing technical object, a method for evaluation of switched reluctance motor system reliability through three-level Markov model provided by the present invention has the following steps: through analysis of the operating condition of the switched reluctance motor drive system under first-level faults, second-level faults and third-level faults, 5 first-level Markov states including 4 valid states and 1 invalid state, 18 second-level Markov states including 14 valid states and 4 invalid states, and 57 third-level Markov states including 43 valid states and 14 invalid states are obtained in total. If initial normal state and final invalid state are also considered, a three-level Markov model will have 62 valid states and 20 invalid states in total. A state transition diagram of the switched reluctance motor drive system under three-level faults is established, and a transition matrix A in valid states under three-level faults is obtained:

$$A = [ \begin{matrix}A 1 & A 11 & A 12 & A 13 \\ O & A 2 & O & O \\ O & O & A 3 & O \\ O & O & O & A 4\end{matrix} ] \qquad ( 1 )$$

State transition matrix A is a square matrix with 62 lines and 62 columns. The lines of state transition matrix A stand for initial valid states, the columns of state transition matrix A stand for next states to be transferred, corresponding transition rates are corresponding elements in state transition matrix A, and the transition rate of a state is the opposite number of the transition probability sum of transition from this state to all states (including invalid states). In Formula (1), A1, A11, A12, A13, A2, A3, A4 are nonzero matrices, O stands for zero matrix, and sub-matrix A1 is a square matrix with 13 lines and 13 columns:

$$A 1 = [ \begin{matrix}B 1 & B 21 & B 31 \\ O & B 2 & O \\ O & O & B 3\end{matrix} ] \qquad ( 2 )$$

In Formula (2), B1, B21, B31, B2, B3 are nonzero matrices, O stands for zero matrix, B21 and B31 of the five nonzero matrices have only one nonzero element, the rest elements are all zero elements, and the five sub-matrices are:

$$\begin{matrix}B 1 = \\ [ \begin{matrix}\begin{matrix}- ( {λ}_{A 1} + \\ {λ}_{A 2} + {λ}_{A 3} + \\ {λ}_{A 4} + {λ}_{A 5} )\end{matrix} & {λ}_{A 1} & 0 & 0 & 0 & 0 \\ 0 & \begin{matrix}- ( {λ}_{B 1} + {λ}_{B 2} + \\ {λ}_{B 3} + {λ}_{B 4} )\end{matrix} & {λ}_{B 1} & 0 & 0 & 0 \\ 0 & 0 & \begin{matrix}- ( {λ}_{C 1} + {λ}_{C 2} + \\ {λ}_{C 3} + {λ}_{C 4} )\end{matrix} & {λ}_{C 1} & {λ}_{C 2} & {λ}_{C 3} \\ & 0 & 0 & - {λ}_{F 1} & 0 & 0 \\ & 0 & 0 & 0 & - {λ}_{F 2} & 0 \\ & 0 & 0 & 0 & 0 & - {λ}_{F 3}\end{matrix} ] & ( 3 ) \\ B 2 = [ \begin{matrix}- ( {λ}_{C 5} + {λ}_{C 6} + {λ}_{C7} ) & {λ}_{C 5} & {λ}_{C 6} \\ 0 & - {λ}_{F 4} & 0 \\ 0 & 0 & - {λ}_{F 5}\end{matrix} ] & ( 4 ) \\ B 3 = [ \begin{matrix}- ( {λ}_{C 8} + {λ}_{C 9} + {λ}_{C 10} + {λ}_{C 11} ) & {λ}_{C 8} & {λ}_{C 9} & {λ}_{C 10} \\ 0 & - {λ}_{F 6} & 0 & 0 \\ 0 & 0 & - {λ}_{F 7} & 0 \\ 0 & 0 & 0 & - {λ}_{F 8}\end{matrix} ] & ( 5 ) \\ B 21 = [ \begin{matrix}0 & 0 & 0 \\ {λ}_{B 2} & 0 & 0 \\ 0 & 0 & 0 \\ 0 & 0 & 0 \\ 0 & 0 & 0 \\ 0 & 0 & 0\end{matrix} ] & ( 6 ) \\ B 31 = [ \begin{matrix}0 & 0 & 0 & 0 \\ {λ}_{B 3} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 7 )\end{matrix}$$

Sub-matrix A2 is a square matrix with 18 lines and 18 columns:

$$A 2 = [ \begin{matrix}B 5 & B 61 & B 71 & B 81 \\ O & B 6 & O & O \\ O & O & B 7 & O \\ O & O & O & B 8\end{matrix} ] \qquad ( 8 )$$

In Formula (8), B5, B61, B71, B81, B6, B7, B8 are nonzero matrices, O stands for zero matrix, B61, B71 and B81 of the seven nonzero matrices have only one nonzero element, the rest elements are all zero elements, and the seven sub-matrices are:

$$\begin{matrix}B 5 = [ \begin{matrix}\begin{matrix}- ( {λ}_{B 5} + {λ}_{B 6} + \\ {λ}_{B 7} + {λ}_{B 8} + {λ}_{B 9} )\end{matrix} & {λ}_{B 5} & 0 & 0 & 0 \\ 0 & \begin{matrix}- ( {λ}_{C 12} + {λ}_{C 13} + \\ {λ}_{C 14} + {λ}_{C 15} )\end{matrix} & {λ}_{C 12} & {λ}_{C 13} & {λ}_{C 14} \\ 0 & 0 & - {λ}_{F 9} & 0 & 0 \\ 0 & 0 & 0 & - {λ}_{F 10} & 0 \\ 0 & 0 & 0 & 0 & - {λ}_{F 11}\end{matrix} ] & ( 9 ) \\ B 6 = [ \begin{matrix}\begin{matrix}- ( {λ}_{C 16} + {λ}_{C 17} + \\ {λ}_{C 18} + {λ}_{C 19} )\end{matrix} & {λ}_{C 16} & {λ}_{C 17} & {λ}_{C 18} \\ 0 & - {λ}_{F 12} & 0 & 0 \\ 0 & 0 & - {λ}_{F 13} & 0 \\ 0 & 0 & 0 & - {λ}_{F 14}\end{matrix} ] & ( 10 ) \\ B 7 = [ \begin{matrix}\begin{matrix}- ( {λ}_{C 20} + {λ}_{C 21} + \\ {λ}_{C 22} + {λ}_{C 23} )\end{matrix} & {λ}_{C 20} & {λ}_{C 21} & {λ}_{C 22} \\ 0 & - {λ}_{F 15} & 0 & 0 \\ 0 & 0 & - {λ}_{F 16} & 0 \\ 0 & 0 & 0 & - {λ}_{F 17}\end{matrix} ] & ( 11 ) \\ B 8 = [ \begin{matrix}\begin{matrix}- ( {λ}_{C 24} + {λ}_{C 25} + \\ {λ}_{C 26} + {λ}_{C 27} + {λ}_{C 28} )\end{matrix} & {λ}_{C 24} & {λ}_{C 25} & {λ}_{C 26} & {λ}_{C 27} \\ 0 & - {λ}_{F 18} & 0 & 0 & 0 \\ 0 & 0 & - {λ}_{F 19} & 0 & 0 \\ 0 & 0 & 0 & - {λ}_{F 20} & 0 \\ 0 & 0 & 0 & 0 & - {λ}_{F 21}\end{matrix} ] & ( 12 ) \\ B 61 = [ \begin{matrix}{λ}_{B 6} & 0 & 0 & 0 \\ 0 & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 13 ) \\ B 71 = [ \begin{matrix}{λ}_{B 7} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 14 ) \\ B 81 = [ \begin{matrix}{λ}_{B 8} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 15 )\end{matrix}$$

Sub-matrix A3 is a square matrix with 12 lines and 12 columns:

$$A 3 = [ \begin{matrix}B 10 & B 111 & B 121 \\ O & B 11 & O \\ 0 & O & B 12\end{matrix} ] \qquad ( 16 )$$

In Formula (16), B10, B111, B121, B11, B12 are nonzero matrices, O stands for zero matrix, B111 and B121 of the five nonzero matrices have only one nonzero element, the rest elements are all zero elements, and the five sub-matrices are:

$$\begin{matrix}B 10 = [ \begin{matrix}\begin{matrix}- ( {λ}_{B 10} + {λ}_{B 11} + \\ {λ}_{B 12} + {λ}_{B 13} )\end{matrix} & {λ}_{B 10} & 0 & 0 \\ 0 & - ( {λ}_{C 29} + {λ}_{C 30} + {λ}_{C 31} ) & {λ}_{C 29} & {λ}_{C 30} \\ 0 & 0 & - {λ}_{F 22} & 0 \\ 0 & 0 & 0 & - {λ}_{F 23}\end{matrix} ] & ( 17 ) \\ B 11 = [ \begin{matrix}\begin{matrix}- ( {λ}_{C 32} + {λ}_{C 33} + \\ {λ}_{C 34} + {λ}_{C 35} )\end{matrix} & {λ}_{C 32} & {λ}_{C 33} & {λ}_{C 34} \\ 0 & - {λ}_{F 24} & 0 & 0 \\ 0 & 0 & - {λ}_{F 25} & 0 \\ 0 & 0 & 0 & - {λ}_{F 26}\end{matrix} ] & ( 18 ) \\ B 12 = [ \begin{matrix}\begin{matrix}- ( {λ}_{C 36} + {λ}_{C 37} + \\ {λ}_{C 38} + {λ}_{C 39} )\end{matrix} & {λ}_{C 36} & {λ}_{C 37} & {λ}_{C 38} \\ 0 & - {λ}_{F 27} & 0 & 0 \\ 0 & 0 & - {λ}_{F 28} & 0 \\ 0 & 0 & 0 & - {λ}_{F 29}\end{matrix} ] & ( 19 ) \\ B 111 = [ \begin{matrix}{λ}_{B 11} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 20 ) \\ B 121 = [ \begin{matrix}{λ}_{B 12} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 21 )\end{matrix}$$

Sub-matrix A4 is a square matrix with 19 lines and 19 columns:

$$A 4 = [ \begin{matrix}B 14 & B 151 & B 161 & B 171 \\ O & B 15 & O & O \\ O & O & B 16 & O \\ O & O & O & B 17\end{matrix} ] \qquad ( 22 )$$

In Formula (22), B14, B151, B161, B171, B15, B16, B17 are nonzero matrices, O stands for zero matrix, B151, B161 and B171 of the seven nonzero matrices have only one nonzero element, the rest elements are all zero elements, and the seven sub-matrices are:

$$\begin{matrix}B 14 = [ \begin{matrix}\begin{matrix}- ( {λ}_{B 14} + {λ}_{B 15} + \\ {λ}_{B 16} + {λ}_{B 17} + \\ {λ}_{B 18} )\end{matrix} & {λ}_{B 14} & 0 & 0 & 0 \\ 0 & \begin{matrix}- ( {λ}_{C 40} + {λ}_{C 41} + \\ {λ}_{C 42} + {λ}_{C 43} )\end{matrix} & {λ}_{C 40} & {λ}_{C 41} & {λ}_{C 42} \\ 0 & 0 & - {λ}_{F 30} & 0 & 0 \\ 0 & 0 & 0 & - {λ}_{F 31} & 0 \\ 0 & 0 & 0 & 0 & - {λ}_{F 32}\end{matrix} ] & ( 23 ) \\ B 15 = [ \begin{matrix}\begin{matrix}- ( {λ}_{C 44} + {λ}_{C 45} + \\ {λ}_{C 46} + {λ}_{C 47} + {λ}_{C 48} )\end{matrix} & {λ}_{C 44} & {λ}_{C 45} & {λ}_{C 46} & {λ}_{C 47} \\ 0 & - {λ}_{F 33} & 0 & 0 & 0 \\ 0 & 0 & - {λ}_{F 34} & 0 & 0 \\ 0 & 0 & 0 & - {λ}_{F 35} & 0 \\ 0 & 0 & 0 & 0 & - {λ}_{F 36}\end{matrix} ] & ( 24 ) \\ B 16 = [ \begin{matrix}\begin{matrix}- ( {λ}_{C 49} + {λ}_{C 50} + \\ {λ}_{C 51} + {λ}_{C 52} )\end{matrix} & {λ}_{C 49} & {λ}_{C 50} & {λ}_{C 51} \\ 0 & - {λ}_{F 37} & 0 & 0 \\ 0 & 0 & - {λ}_{F 38} & 0 \\ 0 & 0 & 0 & - {λ}_{F 39}\end{matrix} ] & ( 25 ) \\ B 17 = [ \begin{matrix}\begin{matrix}- ( {λ}_{C 53} + {λ}_{C 54} + \\ {λ}_{C 55} + {λ}_{C 56} + {λ}_{C 57} )\end{matrix} & {λ}_{C 53} & {λ}_{C 54} & {λ}_{C 55} & {λ}_{C 56} \\ 0 & - {λ}_{F 40} & 0 & 0 & 0 \\ 0 & 0 & - {λ}_{F 41} & 0 & 0 \\ 0 & 0 & 0 & - {λ}_{F 42} & 0 \\ 0 & 0 & 0 & 0 & - {λ}_{F 43}\end{matrix} ] & ( 26 ) \\ B 151 = [ \begin{matrix}{λ}_{B 15} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 27 ) \\ B 161 = [ \begin{matrix}{λ}_{B 16} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 28 ) \\ B 171 = [ \begin{matrix}{λ}_{B 17} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 29 )\end{matrix}$$

In the formulae, λ_{A1}, λ_{A2}, λ_{A3}, λ_{A4}, λ_{A5}, λ_{B1}, λ_{B2}, λ_{B3}, λ_{B4}, λ_{B5}, λ_{B6}, λ_{B7}, λ_{B8}, λ_{B9}, λ_{B10}, λ_{B11}, λ_{B12}, λ_{B13}, λ_{B14}, λ_{B15}, λ_{B16}, λ_{B17}, λ_{B18}, λ_{C1}, λ_{C2}, λ_{C3}, λ_{C4}, λ_{C5}, λ_{C6}, λ_{C7}, λ_{C8}, λ_{C9}, λ_{C10}, λ_{C11}, λ_{C12}, λ_{C13}, λ_{C14}, λ_{C15}, λ_{C16}, λ_{C17}, λ_{C18}, λ_{C19}, λ_{C20}, λ_{C21}, λ_{C22}, λ_{C23}, λ_{C24}, λ_{C25}, λ_{C26}, λ_{C27}, λ_{C28}, λ_{C29}, λ_{C30}, λ_{C31}, λ_{C32}, λ_{C33}, λ_{C34}, λ_{C35}, λ_{C36}, λ_{C37}, λ_{C38}, λ_{C39}, λ_{C40}, λ_{C41}, λ_{C42}, λ_{C43}, λ_{C44}, λ_{C45}, λ_{C46}, λ_{C47}, λ_{C48}, λ_{C49}, λ_{C50}, λ_{C51}, λ_{C52}, λ_{C53}, λ_{C54}, λ_{C55}, λ_{C56}, λ_{C57}, λ_{F1}, λ_{F2}, λ_{F3}, λ_{F4}, λ_{F5}, λ_{F6}, λ_{F7}, λ_{F8}, λ_{F9}, λ_{F10}, λ_{F11}, λ_{F12}, λ_{F13}, λ_{F14}, λ_{F15}, λ_{F16}, λ_{F17}, λ_{F18}, λ_{F19}, λ_{F20}, λ_{F21}, λ_{F22}, λ_{F23}, λ_{F24}, λ_{F25}, λ_{F26}, λ_{F27}, λ_{F28}, λ_{F29}, λ_{F30}, λ_{F31}, λ_{F32}, λ_{F33}, λ_{F34}, λ_{F35}, λ_{F36}, λ_{F37}, λ_{F38}, λ_{F39}, λ_{F40}, λ_{F41}, λ_{F42}, λ_{F43} are state transition rates of three-level Markov model;

By using Formula:

$$P ( t ) \cdot A = \frac{dP ( t )}{dt} \qquad ( 30 )$$

Probability matrix P(t) of the switched reluctance motor system in valid states is attained:

$$P ( t ) = [ \begin{matrix}{P}_{A 1} ( t ) \\ {P}_{A 2} ( t ) \\ {P}_{A 3} ( t ) \\ {P}_{A 4} ( t )\end{matrix} ] \qquad ( 31 )$$

In Formula (31), P_{A1}(t)-P_{A2}(t)-P_{A3}(t) and P_{A4}(t) denote valid-state probabilities in Al submodel, A2 submodel, A3 submodel and A4 submodel, as shown in Formulae (32) to (35):

$$\begin{matrix}{P}_{A 1} ( t ) = [ \begin{matrix}exp ( - 4.81 t ) \\ 0.0686 exp ( - 2.99 t ) - 0.0686 exp ( - 4.81 t ) \\ 0.0202 exp ( - 2.95 t ) - 0.0206 exp ( - 2.99 t ) \\ 0.0128 exp ( - 1.54 t ) - 0.023 exp ( - 2.99 t ) + 0.0103 exp ( - 4.81 t ) \\ 0.0246 exp ( - 0.237 t ) - 0.06 exp ( - 2.99 t ) + 0.0374 exp ( - 4.81 t ) \\ 1.04 e - 4 exp ( - 2.95 t ) + 1.34 e - 5 exp ( - 4.43 t ) \\ 0.0516 exp ( - 2.99 t ) - 0.0525 exp ( - 2.95 t ) + 0.00134 exp ( - 2.01 t ) \\ 0.009 exp ( - 2.95 t ) - 0.009 exp ( - 2.99 t ) + 7.97 e - 4 exp ( - 4.04 t ) \\ 8.85 e - 4 exp ( - 3.67 t ) - 6.9 e - 4 exp ( - 2.99 t ) - 2.5 e - 4 exp ( - 4.81 t ) \\ 0.001 exp ( - 0.237 t ) - 0.013 exp ( - 2.99 t ) + 0.02 exp ( - 4.07 t ) \\ 3.48 e - 4 exp ( - 3.96 t ) - 1.37 e - 4 exp ( - 4.81 t ) \\ 0.145 exp ( - 3.19 t ) + 0.009 exp ( - 1.54 t ) - 0.147 exp ( - 2.99 t ) \\ 0.0103 exp ( - 3.64 t ) - 0.009 exp ( - 2.99 t ) - 0.002 exp ( - 4.81 t )\end{matrix} ] \\ & ( 32 ) \\ {P}_{A 2} ( t ) = [ \begin{matrix}0.00659 exp ( - 3.08 t ) - 0.00659 exp ( - 4.81 t ) \\ 0.006 exp ( - 2.96 t ) - 0.006 exp ( - 3.08 t ) + 4.43 e - 4 exp ( - 4.81 t ) \\ 0.001 exp ( - 3.04 t ) - 0.001 exp ( - 3.08 t ) \\ 0.002 exp ( - 0.404 t ) - 0.006 exp ( - 3.08 t ) + 0.004 exp ( - 4.81 t ) \\ 0.001 exp ( - 1.83 t ) - 0.002 exp ( - 3.08 t ) + 0.00108 exp ( - 4.81 t ) \\ 3.57 e - 5 exp ( 2.96 t ) - 4.23 e - 5 exp ( - 3.08 t ) + 1.28 e - 5 exp ( - 4.27 t ) \\ 0.00976 exp ( - 3.5 t ) - 0.0342 exp ( - 3.08 t ) + 0.0253 exp ( - 2.96 t ) \\ 1.19 e - 4 exp ( - 3.04 t ) + 1.36 e - 5 exp ( - 4.27 t ) \\ 4.24 e - 4 exp ( - 3.74 t ) - 0.00441 exp ( - 3.08 t ) + 0.00405 exp ( - 3.04 t ) \\ 5.2 e - 4 exp ( - 3.04 t ) - 5.53 e - 4 exp ( - 3.08 t ) + 5.41 e - 5 exp ( - 4.14 t ) \\ 0.00186 exp ( - 3.55 t ) + 9.4 e - 5 exp ( - 0.404 t ) - 0.00159 exp ( - 3.08 t ) \\ 9.03 e - 5 exp ( - 3.74 t ) - 2.61 e - 5 exp ( - 4.81 t ) \\ 0.00523 exp ( - 3.43 t ) - 0.00472 exp ( - 3.08 t ) - 7.24 e - 4 exp ( - 4.81 t ) \\ 4.36 e - 4 exp ( - 3.96 t ) + 8.72 e - 5 exp ( - 1.83 t ) - 3.66 e - 4 exp ( - 3.08 t ) \\ 4.88 e - 6 exp ( - 1.83 t ) + 2.58 e - 5 exp ( - 4.14 t ) \\ 0.00608 exp ( - 3.73 t ) + 0.00114 exp ( - 1.83 t ) - 0.00575 exp ( - 3.08 t ) \\ 8.7 e - 4 exp ( - 3.83 t ) - 7.88 e - 4 exp ( - 3.08 t ) - 2.53 e - 4 exp ( - 4.81 t ) \\ 6.48 e - 4 exp ( - 0.237 t ) - 7.37 e - 4 exp ( 0.476 t ) + 1.84 e - 4 exp ( - 3.55 t )\end{matrix} ] & ( 33 ) \\ {P}_{A 3} ( t ) = [ \begin{matrix}0.575 exp ( - 0.476 t ) - 0.575 exp ( - 4.81 t ) \\ 0.284 exp ( - 0.237 t ) - 0.299 exp ( - 0.476 t ) + 0.015 exp ( - 4.81 t ) \\ 0.037 exp ( - 0.361 t ) - 0.038 exp ( - 0.476 t ) \\ 1.72 exp - ( - 0.364 t ) - 1.77 exp ( - 0.476 t ) + 0.0445 exp ( - 4.81 t ) \\ 0.0216 exp ( - 0.237 t ) - 0.0248 exp ( - 0.476 t ) + 0.00547 exp ( - 3.24 t ) \\ 0.00115 exp ( - 0.361 t ) - 0.00121 exp ( - 0.476 t ) + 3.54 e - 4 exp ( - 4.39 t ) \\ 6.67 e - 5 exp ( - 0.361 t ) - 7.04 e - 5 exp - ( 0.476 t ) + 3.48 e - 5 exp ( - 4.57 t ) \\ 0.00218 exp ( - 0.361 t ) - 0.00231 exp ( - 0.476 t ) + 5.35 e - 4 exp ( - 4.26 t ) \\ 0.0578 exp ( - 0.364 t ) + 0.00756 exp ( - 4.81 t ) + 0.0109 exp ( - 4.07 t ) \\ 0.0184 exp ( - 3.95 t ) - 0.117 exp ( - 0.476 t ) + 0.11 exp ( - 0.364 t ) \\ 0.00335 exp ( - 0.364 t ) - 0.00354 exp ( - 0.476 t ) + 8.03 e - 4 exp ( - 4.26 t ) \\ 0.00307 exp ( - 3.96 t ) - 1.45 e - 4 exp ( - 1.82 t ) - 0.005 exp ( - 4.38 t )\end{matrix} ] & ( 34 ) \\ {P}_{A 4} ( t ) = [ \begin{matrix}3.93 exp ( - 4.38 t ) - 4.55 exp ( - 4.81 t ) \\ 0.0259 exp ( - 1.73 t ) + 0.159 exp ( - 4.81 t ) - 0.18 exp ( - 4.38 t ) \\ 0.002 exp ( - 1.82 t ) + 0.014 exp ( - 4.81 t ) - 0.017 exp ( - 4.38 t ) \\ 0.137 exp ( - 0.364 t ) + 1.28 exp ( - 4.81 t ) - 1.42 exp ( - 4.38 t ) \\ 0.056 exp ( - 1.72 t ) + 0.346 exp ( - 4.81 t ) - 0.402 exp ( - 4.38 t ) \\ 1.32 e - 4 exp ( - 1.73 t ) - 0.00299 exp ( - 3.96 t ) + 0.00497 exp ( - 4.38 t ) \\ 0.0248 exp ( - 1.73 t ) - 0.114 exp ( - 3.24 t ) + 0.236 exp ( - 4.38 t ) \\ 0.00367 exp ( - 1.73 t ) - 0.035 exp ( - 3.64 t ) - 0.0371 exp ( - 4.81 t ) \\ 5.47 e - 4 exp ( - 4.38 t ) - 3.88 e - 4 exp ( - 4.14 t ) \\ 0.00183 exp ( - 1.82 t ) - 0.0194 exp ( - 4.81 t ) + 0.0379 exp ( - 4.38 t ) \\ 0.00476 exp ( - 3.83 t ) - 0.00409 exp ( - 4.81 t ) + 0.00851 exp ( - 4.38 t ) \\ 0.0595 exp ( - 3.24 t ) - 0.102 exp ( - 4.81 t ) + 0.155 exp ( - 4.38 t ) \\ 0.0046 exp ( - 3.42 t ) - 0.00702 exp ( - 4.81 t ) + 0.0113 exp ( - 4.38 t ) \\ 0.0115 exp ( - 0.364 t ) - 0.0952 exp ( - 3.11 t ) + 0.257 exp ( - 4.38 t ) \\ 0.00405 exp ( - 1.72 t ) - 0.0315 exp ( - 4.81 t ) + 0.0535 exp ( - 4.38 t ) \\ 0.0103 exp ( - 3.64 t ) + 0.001 exp ( - 1.54 t ) - 0.009 exp ( - 2.99 t ) \\ 0.00607 exp ( - 4.38 t ) - 0.00308 exp ( - 3.63 t ) - 0.00332 exp ( - 4.8 t ) \\ 0.0547 exp ( - 1.72 t ) - 0.245 exp ( - 3.22 t ) + 0.51 exp ( - 4.38 t ) \\ 0.044 exp ( - 4.38 t ) - 0.0211 exp ( - 3.32 t ) - 0.027 exp ( - 4.81 t )\end{matrix} ] & ( 35 )\end{matrix}$$

In Formulae (32) to (35), exp denotes an exponential function, t denotes time, and A stands for a state transition matrix;

The sum of all elements of probability matrix P(t) in valid states is calculated with Formula (31) to obtain reliability function R(t) of the switched reluctance motor system:

$$R ( t ) = 0.0018 exp ( - 3.96 ) + 0.0184 exp ( - 3.95 t ) + 8.7 e - 4 exp ( - 3.83 t ) - 0.004 exp ( - 3.83 t ) - 1.74 exp ( - 0.476 t ) + 0.332 exp ( - 0.237 t ) + 5.14 e - 4 exp ( - 3.74 t ) - 0.0142 exp ( - 3.73 t ) + 8.85 e - 4 exp ( - 3.67 t ) + 0.0029 exp ( - 1.83 t ) + 0.01 exp ( - 3.64 t ) - 0.035 exp ( - 3.64 t ) + 0.004 exp ( - 1.82 t ) - 0.003 exp ( - 3.63 t ) - 0.011 exp ( - 3.55 t ) + 0.0544 exp ( - 1.73 t ) - 0.026 exp ( - 3.44 t ) + 0.119 exp ( - 1.72 t ) + 0.005 exp ( - 3.43 t ) - 0.0046 exp ( - 3.42 t ) - 0.0211 exp ( - 3.32 t ) - 0.108 exp ( - 3.24 t ) - 0.0595 exp ( - 3.24 t ) + 0.00269 exp ( - 0.404 t ) - 0.245 exp ( - 3.22 t ) + 0.145 exp ( - 3.19 t ) - 0.0952 exp ( - 3.11 t ) - 0.0662 exp ( - 3.08 t ) + 0.024 exp ( - 1.54 t ) + 0.005 exp ( - 3.04 t ) - 0.166 exp ( - 2.99 t ) + 0.0345 exp ( - 2.96 t ) - 0.0231 exp ( - 2.95 t ) + 2.05 exp ( - 0.364 t ) + 0.04 exp ( - 0.36 t ) - 2.59 exp ( - 4.81 t ) + 3.48 e - 5 exp ( - 4.57 t ) + 1.34 e - 5 exp ( - 4.43 t ) + 3.54 e - 4 exp ( - 4.39 t ) + 3.3 exp ( - 4.38 t ) + 1.28 e - 5 exp ( - 4.27 t ) + 1.36 e - 5 exp ( - 4.27 t ) + 0.0013 exp ( - 4.26 t ) - 3.08 e - 4 exp ( - 4.14 t ) + 0.01 exp ( - 4.07 t ) + 0.023 exp ( - 4.07 t ) + 7.97 e - 4 exp ( - 4.04 ) + 0.001 exp ( - 2.01 t ) \qquad ( 36 )$$

From reliability function R(t), mean time between failure (MTTF) of the switched reluctance motor system is calculated:

$$MTIF = {\int }_{0}^{∞} R ( t ) dt \qquad ( 37 )$$

Thereby, evaluation of switched reluctance motor system reliability is realized through quantitative analysis of three-level Markov model.

Beneficial effect: The method for evaluation of switched reluctance motor system reliability through quantitative analysis of a three-level Markov model not only effectively raises reliability evaluation accuracy but also if the switched reluctance motor system can tolerate faults at or above three-level, the three-level Markov model can represent all possible operating states of the switched reluctance motor system under three-level faults. If the output of the system is in an allowable range, the current state may be reflected in the Markov model to maximally represent the error tolerance of the switched reluctance motor system; meanwhile the method based on state transition in Markov modeling process uses the final influence of all possible faults on the switched reluctance motor system as a state, significantly reduces the number of states and raises the speed of quantitative evaluation of reliability. The accuracy and speed of reliability evaluation can meet the requirements of high-reliability switched reluctance motor systems. Three-level Markov model has the highest accuracy and is applicable to an environment with a large number of equivalent faults and relatively relaxing fault criteria.

### BRIEF DESCRIPTION OF THE DRAWINGS

FIG. 1 is a Markov state transition diagram of switched reluctance motor system under three-level faults of the present invention;

FIG. 2 is A1 Markov submodel of the present invention;

FIG. 3 is A2 Markov submodel of the present invention;

FIG. 4 is A3 Markov submodel of the present invention;

FIG. 5 is A4 Markov submodel of the present invention;

FIG. 6 is a schematic of a switched reluctance motor system of the present invention, comprising a three-phase 12/8-structure switched reluctance motor and a three-phase biswitch power converter;

FIG. 7 is a reliability function curve obtained from the Markov reliability model for switched reluctance motor system of the present invention.

### DETAILED DESCRIPTION

Below, the present invention is further described by referring to the embodiments and accompanying drawings:

Based on the manifestations of switched reluctance motor system after occurrence of a first-level fault,

Based on the manifestations of switched reluctance motor system after occurrence of a first-level fault, 17 first-level faults of the switched reluctance motor system are equivalent to 4 valid states and 1 invalid state in Markov space. The 4 valid states are capacitor open-circuit, turn-to-turn short-circuit, default phase and down MOSFET short-circuit survival states, expressed with A1, A2, A3 and A4 respectively. Invalid state is expressed with A5. The transition rates of 5 Markov states under first-level faults are shown in Table 1.

TABLE 1
State transition rates of Markov model under first-level faults

| No. | Type of First-Level Fault | A1 | A2 | A3 | A4 | A5 |
|---|---|---|---|---|---|---|
| 1 | Capacitor Open-circuit (CO) | 1 | 0 | 0 | 0 | 0 |
| 2 | Capacitor Short-circuit (CS) | 0 | 0 | 0 | 0 | 1 |
| 3 | Down MOSFET Short-circuit | 0 | 0 | 0.34 | 0.54 | 0.12 |
| | (DMS) | | | | | |
| 4 | Down MOSFET Open-circuit | 0 | 0 | 0.88 | 0 | 0.12 |
| | (DMO) | | | | | |
| 5 | Upper MOSFET Short-circuit | 0 | 0 | 0.43 | 0 | 0.57 |
| | (UMS) | | | | | |
| 6 | Upper MOSFET Open-circuit | 0 | 0 | 0.88 | 0 | 0.12 |
| | (UMO) | | | | | |
| 7 | Upper Diode Short-circuit | 0 | 0 | 0.88 | 0 | 0.12 |
| | (UDS) | | | | | |
| 8 | Upper Diode Open-circuit | 0 | 0 | 0 | 0 | 1 |
| | (UDO) | | | | | |
| 9 | Down Diode Short-circuit | 0 | 0 | 0.88 | 0 | 0.12 |
| | (DDS) | | | | | |
| 10 | Down Diode Open-circuit | 0 | 0 | 0 | 0 | 1 |
| | (DDO) | | | | | |
| 11 | Turn-to-turn Short-circuit (TTS) | 0 | 0.1 | 0 | 0 | 0.9 |
| 12 | Pole-to-pole Short-circuit (POS) | 0 | 0 | 0 | 0 | 1 |
| 13 | Phase-to-ground Short-circuit | 0 | 0 | 0 | 0 | 1 |
| | (PGS) | | | | | |
| 14 | Phase-to-phase Short-circuit | 0 | 0 | 0 | 0 | 1 |
| | (PHS) | | | | | |
| 15 | Turn-to-turn Open-circuit | 0 | 0 | 0.88 | 0 | 0.12 |
| | (TTO) | | | | | |
| 16 | Position Sensor Short-circuit | 0 | 0 | 0.34 | 0.54 | 0.12 |
| | (PPS) | | | | | |
| 17 | Position Sensor Open-circuit | 0 | 0 | 0.88 | 0 | 0.12 |
| | (PPO) | | | | | |

On the basis of first-level Markov states, in consideration of possible second-level faults, the possible second-level faults are summarized into six types: capacitor open-circuit, turn-to-turn short-circuit, upper MOSFET short-circuit, down MOSFET short-circuit , default phase and failure. In A1 state, there may be five types of faults: turn-to-turn short-circuit, upper MOSFET short-circuit, down MOSFET short-circuit, default phase and failure. The states after occurrence of faults are summarized into 4 Markov states: B1 to B4. The state transition rates of Markov model under second-level faults in A1 state are shown in Table 2.

TABLE 2
State transition rates of Markov model
under second-level faults in A1 state

| No. | Type of Second-Level Fault | B1 | B2 | B3 | B4 |
|---|---|---|---|---|---|
| 1 | Turn-to-turn Short-circuit (TTS) | 0.1 | 0 | 0.9 | 0 |
| 2 | Upper MOSFET Short-circuit (UMS) | 0 | 0.43 | 0 | 0.57 |
| 3 | Down MOSFET Short-circuit (DMS) | 0 | 0.34 | 0.54 | 0.12 |
| 4 | Default Phase (DPH) | 0 | 0.88 | 0 | 0.12 |
| 5 | Failure (F) | 0 | 0 | 0 | 1 |

In A2 state, there may be 6 types of faults: capacitor open-circuit, turn-to-turn short-circuit, upper MOSFET short-circuit, down MOSFET short-circuit, default phase and failure. The corresponding Markov states are B5 to B9. The state transition rates of Markov model under second-level faults in A2 state are shown in Table 3.

TABLE 3
State transition rates of Markov model under second-level faults in A2
state

| No. | Type of Second-Level Fault | B5 | B6 | B7 | B8 | B9 |
|---|---|---|---|---|---|---|
| 1 | Capacitor Open-circuit (CO) | 1 | 0 | 0 | 0 | 0 |
| 2 | Turn-to-turn Short-circuit (TTS) | 0 | 0.1 | 0.9 | 0 | 0 |
| 3 | Upper MOSFET Short-circuit | 0 | 0 | 0.43 | 0 | 0.57 |
| | (UMS) | | | | | |
| 4 | Down MOSFET Short-circuit | 0 | 0 | 0.34 | 0.54 | 0.12 |
| | (DMS) | | | | | |
| 5 | Default Phase (DPH) | 0 | 0 | 0.88 | 0 | 0.12 |
| 6 | Failure (F) | 0 | 0 | 0 | 0 | 1 |

In A3 state, there may be 6 types of faults: capacitor open-circuit, turn-to-turn short-circuit, upper MOSFET short-circuit, down MOSFET short-circuit, default phase and failure, equivalent to Markov states B10 to B13. The state transition rates of Markov model under second-level faults in A3 state are shown in Table 4.

TABLE 4
State transition rates of Markov model
under second-level faults in A3 state

| No. | Type of Second-Level Fault | B10 | B11 | B12 | B13 |
|---|---|---|---|---|---|
| 1 | Capacitor Open-circuit (CO) | 1 | 0 | 0 | 0 |
| 2 | Turn-to-turn Short-circuit (TTS) | 0 | 0.1 | 0.9 | 0 |
| 3 | Upper MOSFET Short-circuit (UMS) | 0 | 0 | 0 | 1 |
| 4 | Down MOSFET Short-circuit (DMS) | 0 | 0 | 0.4 | 0.6 |
| 5 | Default Phase (DPH) | 0 | 0 | 0 | 1 |
| 6 | Failure (F) | 0 | 0 | 0 | 1 |

In A4 state, there may be 6 types of faults: capacitor open-circuit, turn-to-turn short-circuit, upper MOSFET short-circuit, down MOSFET short-circuit, default phase and failure, equivalent to Markov states B14 to B18. The state transition rates of Markov model under second-level faults in A4 state are shown in Table 5.

TABLE 5
State transition rates of Markov model under second-level faults in
A4 state

| No. | Type of Second-Level Fault | B14 | B15 | B16 | B17 | B18 |
|---|---|---|---|---|---|---|
| 1 | Capacitor Open-circuit (CO) | 1 | 0 | 0 | 0 | 0 |
| 2 | Turn-to-turn Short-circuit | 0 | 0.1 | 0.9 | 0 | 0 |
| | (TTS) | | | | | |
| 3 | Upper MOSFET Short-circuit | 0 | 0 | 0.35 | 0 | 0.65 |
| | (UMS) | | | | | |
| 4 | Down MOSFET Short-circuit | 0 | 0 | 0.4 | 0.45 | 0.15 |
| | (DMS) | | | | | |
| 5 | Default Phase (DPH) | 0 | 0 | 0.4 | 0.38 | 0.22 |
| 6 | Failure (F) | 0 | 0 | 0 | 0 | 1 |

On the basis of second-level Markov states, in consideration of possible third-level faults, likewise six types of faults may be summarized. They are capacitor open-circuit, turn-to-turn short-circuit, upper MOSFET short-circuit, down MOSFET short-circuit, default phase and failure. In B1 state, there may be five types of faults: turn-to-turn short-circuit, upper MOSFET short-circuit, down MOSFET short-circuit, default phase and failure. The states after occurrence of faults are summarized into 4 Markov states: C1 to C4. The corresponding transition rates are shown in Table 6.

TABLE 6
State transition rates of Markov model
under third-level faults in B1 state

| No. | Type of Third-Level Fault | C1 | C2 | C3 | C4 |
|---|---|---|---|---|---|
| 1 | Turn-to-turn Short-circuit (TTS) | 0.1 | 0.9 | 0 | 0 |
| 2 | Upper MOSFET Short-circuit (UMS) | 0 | 0.43 | 0 | 0.57 |
| 3 | Down MOSFET Short-circuit (DMS) | 0 | 0.34 | 0.54 | 0.12 |
| 4 | Default Phase (DPH) | 0 | 0.88 | 0 | 0.12 |
| 5 | Failure (F) | 0 | 0 | 0 | 1 |

In B2 state, there may be 5 types of faults: turn-to-turn short-circuit, upper MOSFET short-circuit, down MOSFET short-circuit, default phase and failure. The states after occurrence of faults are summarized into 3 Markov states: C5 to C7. The corresponding transition rates are shown in Table 7.

TABLE 7
State transition rates of Markov model
under third-level faults in B2 state

| No. | Type of Third-Level Fault | C5 | C6 | C7 |
|---|---|---|---|---|
| 1 | Turn-to-turn Short-circuit (TTS) | 0.1 | 0 | 0.9 |
| 2 | Upper MOSFET Short-circuit (UMS) | 0 | 0 | 1 |
| 3 | Down MOSFET Short-circuit (DMS) | 0 | 0.38 | 0.62 |
| 4 | Default Phase (DPH) | 0 | 0 | 1 |
| 5 | Failure (F) | 0 | 0 | 1 |

In B3 state, there may be 5 types of faults: turn-to-turn short-circuit, upper MOSFET short-circuit, down MOSFET short-circuit, default phase and failure. The states after occurrence of faults are summarized into 4 Markov states: C8 to C11. The corresponding transition rates are shown in Table 8.

TABLE 8
State transition rates of Markov model
under third-level faults in B3 state

| No. | Type of Third-Level Fault | C8 | C9 | C10 | C11 |
|---|---|---|---|---|---|
| 1 | Turn-to-turn Short-circuit (TTS) | 0.1 | 0.9 | 0 | 0 |
| 2 | Upper MOSFET Short-circuit (UMS) | 0 | 0.35 | 0 | 0.65 |
| 3 | Down MOSFET Short-circuit (DMS) | 0 | 0.4 | 0.45 | 0.15 |
| 4 | Default Phase (DPH) | 0 | 0.4 | 0.38 | 0.22 |
| 5 | Failure (F) | 0 | 0 | 0 | 1 |

In B5 state, there may be 5 types of faults: turn-to-turn short-circuit, upper MOSFET short-circuit, down MOSFET short-circuit, default phase and failure. The states after occurrence of faults are summarized into 4 Markov states: C12 to C15. The corresponding transition rates are shown in Table 9.

TABLE 9
State transition rates of Markov model
under third-level faults in B5 state

| No. | Type of Third-Level Fault | C12 | C13 | C14 | C15 |
|---|---|---|---|---|---|
| 1 | Turn-to-turn Short-circuit (TTS) | 0.1 | 0.9 | 0 | 0 |
| 2 | Upper MOSFET Short-circuit (UMS) | 0 | 0.43 | 0 | 0.57 |
| 3 | Down MOSFET Short-circuit (DMS) | 0 | 0.34 | 0.54 | 0.12 |
| 4 | Default Phase (DPH) | 0 | 0 | 0.88 | 0.12 |
| 5 | Failure (F) | 0 | 0 | 0 | 1 |

In B6 state, there may be 6 types of faults: capacitor open-circuit, turn-to-turn short-circuit, upper MOSFET short-circuit, down MOSFET short-circuit, default phase and failure, equivalent to Markov states C16 to C19. The state transition rates of Markov model under third-level faults in B6 state are shown in Table 10.

TABLE 10
State transition rates of Markov model
under third-level faults in B6 state

| No. | Type of Third-Level Fault | C16 | C17 | C18 | C19 |
|---|---|---|---|---|---|
| 1 | Capacitor Open-circuit (CO) | 1 | 0 | 0 | 0 |
| 2 | Turn-to-turn Short-circuit (TTS) | 0 | 0 | 0 | 1 |
| 3 | Upper MOSFET Short-circuit (UMS) | 0 | 0.43 | 0 | 0.57 |
| 4 | Down MOSFET Short-circuit (DMS) | 0 | 0.34 | 0.54 | 0.12 |
| 5 | Default Phase (DPH) | 0 | 0.88 | 0 | 0.12 |
| 6 | Failure (F) | 0 | 0 | 0 | 1 |

In B7 state, there may be 6 types of faults: capacitor open-circuit, turn-to-turn short-circuit, upper MOSFET short-circuit, down MOSFET short-circuit, default phase and failure, equivalent to Markov state C20 to C23. The state transition rates of Markov model under third-level faults in B7 state are shown in Table 11.

TABLE 11
State transition rates of Markov model
under third-level faults in B7 state

| No. | Type of Third-Level Fault | C20 | C21 | C22 | C23 |
|---|---|---|---|---|---|
| 1 | Capacitor Open-circuit (CO) | 1 | 0 | 0 | 0 |
| 2 | Turn-to-turn Short-circuit (TTS) | 0 | 0.1 | 0 | 0.9 |
| 3 | Upper MOSFET Short-circuit (UMS) | 0 | 0 | 0 | 1 |
| 4 | Down MOSFET Short-circuit (DMS) | 0 | 0.4 | 0.38 | 0.22 |
| 5 | Default Phase (DPH) | 0 | 0 | 0 | 1 |
| 6 | Failure (F) | 0 | 0 | 0 | 1 |

In B8 state, there may be 6 types of faults: capacitor open-circuit, turn-to-turn short-circuit, upper MOSFET short-circuit, down MOSFET short-circuit, default phase and failure, equivalent to Markov states C24 to C28. The state transition rates of Markov model under third-level faults in B8 state are shown in Table 12.

TABLE 12
State transition rates of Markov model under third-level faults in B8 state

| No. | Type of Third-Level Fault | C24 | C25 | C26 | C27 | C28 |
|---|---|---|---|---|---|---|
| 1 | Capacitor Open-circuit (CO) | 1 | 0 | 0 | 0 | 0 |
| 2 | Turn-to-turn Short-circuit | 0 | 0.1 | 0.9 | 0 | 0 |
| | (TTS) | | | | | |
| 3 | Upper MOSFET Short-circuit | 0 | 0 | 0.35 | 0 | 0.65 |
| | (UMS) | | | | | |
| 4 | Down MOSFET Short-circuit | 0 | 0 | 0.4 | 0.45 | 0.15 |
| | (DMS) | | | | | |
| 5 | Default Phase (DPH) | 0 | 0 | 0.4 | 0.38 | 0.22 |
| 6 | Failure (F) | 0 | 0 | 0 | 0 | 1 |

In B10 state, there may be 5 types of faults: turn-to-turn short-circuit, upper MOSFET short-circuit, down MOSFET short-circuit, default phase and failure, equivalent to Markov states C29 to C31. The state transition rates of Markov model under third-level faults in B10 state are shown in Table 13.

TABLE 13
State transition rates of Markov model
under third-level faults in B10 state

| No. | Type of Third-Level Fault | C29 | C30 | C31 |
|---|---|---|---|---|
| 1 | Turn-to-turn Short-circuit (TTS) | 0.1 | 0 | 0.9 |
| 2 | Upper MOSFET Short-circuit (UMS) | 0 | 0 | 1 |
| 3 | Down MOSFET Short-circuit (DMS) | 0 | 0.38 | 0.62 |
| 4 | Default Phase (DPH) | 0 | 0 | 1 |
| 5 | Failure (F) | 0 | 0 | 1 |

In B11 state, there may be 6 types of faults: capacitor open-circuit, turn-to-turn short-circuit, upper MOSFET short-circuit, down MOSFET short-circuit, default phase and failure, equivalent to Markov states C32 to C35. The state transition rates of Markov model under third-level faults in B11 state are shown in Table 14.

TABLE 14
State transition rates of Markov model
under third-level faults in B11 state

| No. | Type of Third-Level Fault | C32 | C33 | C34 | C35 |
|---|---|---|---|---|---|
| 1 | capacitor open-circuit (CO) | 1 | 0 | 0 | 0 |
| 2 | Turn-to-turn Short-circuit (TTS) | 0 | 0.1 | 0 | 0.9 |
| 3 | Upper MOSFET Short-circuit (UMS) | 0 | 0 | 0 | 1 |
| 4 | Down MOSFET Short-circuit (DMS) | 0 | 0 | 0.38 | 0.62 |
| 5 | Default Phase (DPH) | 0 | 0 | 0 | 1 |
| 6 | Failure (F) | 0 | 0 | 0 | 1 |

In B12 state, there may be 6 types of faults: capacitor open-circuit, turn-to-turn short-circuit, upper MOSFET short-circuit, down MOSFET short-circuit, default phase and failure, equivalent to Markov states C36 to C39. The state transition rates of Markov model under third-level faults in B12 state are shown in Table 15.

TABLE 15
State transition rates of Markov model
under third-level faults in B12 state

| No. | Type of Third-Level Fault | C36 | C37 | C38 | C39 |
|---|---|---|---|---|---|
| 1 | Capacitor Open-circuit (CO) | 1 | 0 | 0 | 0 |
| 2 | Turn-to-turn Short-circuit (TTS) | 0 | 0.1 | 0 | 0.9 |
| 3 | Upper MOSFET Short-circuit (UMS) | 0 | 0 | 0 | 1 |
| 4 | Down MOSFET Short-circuit (DMS) | 0 | 0 | 0.38 | 0.62 |
| 5 | Default Phase (DPH) | 0 | 0 | 0 | 1 |
| 6 | Failure (F) | 0 | 0 | 0 | 1 |

In B14 state, there may be 5 types of faults: turn-to-turn short-circuit, upper MOSFET short-circuit, down MOSFET short-circuit, default phase and failure, equivalent to Markov states C40 to C43. The state transition rates of Markov model under third-level faults in B14 state are shown in Table 16.

TABLE 16
State transition rates of Markov model
under third-level faults in B14 state

| No. | Type of Third-Level Fault | C40 | C41 | C42 | C43 |
|---|---|---|---|---|---|
| 1 | Turn-to-turn Short-circuit | 0 | 0.1 | 0.9 | 0 |
| | (TTS) | | | | |
| 2 | Upper MOSFET Short-circuit | 0 | 0.35 | 0 | 0.65 |
| | (UMS) | | | | |
| 3 | Down MOSFET Short-circuit | 0 | 0.4 | 0.45 | 0.15 |
| | (DMS) | | | | |
| 4 | Default Phase (DPH) | 0 | 0.4 | 0.38 | 0.22 |
| 5 | Failure (F) | 0 | 0 | 0 | 1 |

In B15 state, there may be 6 types of faults: capacitor open-circuit, turn-to-turn short-circuit, upper MOSFET short-circuit, down MOSFET short-circuit, default phase and failure, equivalent to Markov states C44 to C48. The state transition rates of Markov model under third-level faults in B15 state are shown in Table 17.

TABLE 17
State transition rates of Markov model under third-level faults in B15 state

| No. | Type of Third-Level Fault | C44 | C45 | C46 | C47 | C48 |
|---|---|---|---|---|---|---|
| 1 | Capacitor Open-circuit (CO) | 1 | 0 | 0 | 0 | 0 |
| 2 | Turn-to-turn Short-circuit | 0 | 0.1 | 0.9 | 0 | 0 |
| | (TTS) | | | | | |
| 3 | Upper MOSFET Short-circuit | 0 | 0 | 0.35 | 0 | 0.65 |
| | (UMS) | | | | | |
| 4 | Down MOSFET Short-circuit | 0 | 0 | 0.4 | 0.45 | 0.15 |
| | (DMS) | | | | | |
| 5 | Default Phase (DPH) | 0 | 0 | 0.4 | 0.38 | 0.22 |
| 6 | Failure (F) | 0 | 0 | 0 | 0 | 1 |

In B16 state, there may be 6 types of faults: capacitor open-circuit, turn-to-turn short-circuit, upper MOSFET short-circuit, down MOSFET short-circuit, default phase and failure, equivalent to Markov states C49 to C52. The state transition rates of Markov model under third-level faults in B16 state are shown in Table 18.

TABLE 18
State transition rates of Markov model
under third-level faults in B16 state

| No. | Type of Third-Level Fault | C49 | C50 | C51 | C52 |
|---|---|---|---|---|---|
| 1 | Capacitor Open-circuit (CO) | 1 | 0 | 0 | 0 |
| 2 | Turn-to-turn Short-circuit (TTS) | 0 | 0.1 | 0 | 0.9 |
| 3 | Upper MOSFET Short-circuit (UMS) | 0 | 0 | 0 | 1 |
| 4 | Down MOSFET Short-circuit (DMS) | 0 | 0 | 0.4 | 0.6 |
| 5 | Default Phase (DPH) | 0 | 0 | 0 | 1 |
| 6 | Failure (F) | 0 | 0 | 0 | 1 |

In B17 state, there may be 6 types of faults: capacitor open-circuit, turn-to-turn short-circuit, upper MOSFET short-circuit, down MOSFET short-circuit, default phase and failure, equivalent to Markov states C53 to C57. The state transition rates of Markov model under third-level faults in B17 state are shown in Table 19.

TABLE 19
State transition rates of Markov model under third-level faults in B17 state

| No. | Type of Third-Level Fault | C53 | C54 | C55 | C56 | C57 |
|---|---|---|---|---|---|---|
| 1 | Capacitor Open-circuit (CO) | 1 | 0 | 0 | 0 | 0 |
| 2 | Turn-to-turn Short-circuit | 0 | 0.1 | 0.9 | 0 | 0 |
| | (TTS) | | | | | |
| 3 | Upper MOSFET Short-circuit | 0 | 0 | 0.35 | 0 | 0.65 |
| | (UMS) | | | | | |
| 4 | Down MOSFET Short-circuit | 0 | 0 | 0.4 | 0.45 | 0.15 |
| | (DMS) | | | | | |
| 5 | Default Phase (DPH) | 0 | 0 | 0.4 | 0.38 | 0.22 |
| 6 | Failure (F) | 0 | 0 | 0 | 0 | 1 |

The above default phase fault contains the following circumstances: down MOSFET open-circuit, upper MOSFET open-circuit, upper diode short-circuit, down diode short-circuit, turn-to-turn open-circuit and position sensor open-circuit. Capacitor short-circuit, upper diode open-circuit, down diode open-circuit, pole-to-pole short-circuit, phase-to-ground short-circuit and phase-to-phase short-circuit constitute failure faults.

Through analyzing the operating condition of a switched reluctance motor drive system under first-level faults, second-level faults and third-level faults, 5 first-level Markov states including 4 valid states and 1 invalid state, 18 second-level Markov states including 14 valid states and 4 invalid states, and 57 third-level Markov states including 43 valid states and 14 invalid states are obtained in total. If initial normal state and final invalid state are also considered, a three-level Markov model will have 62 valid states and 20 invalid states in total.

If a fault above four-level occurs to the switched reluctance motor system, generally it is considered that the switched reluctance motor system is failed.

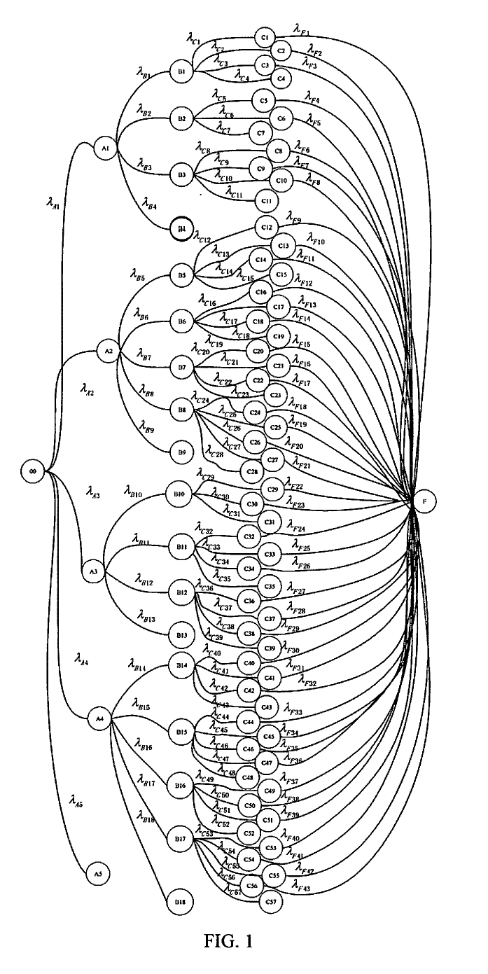

To summarize the above analysis, a state transition diagram of the switched reluctance motor system under a three-level Markov model is obtained, as shown in FIG. 1. Markov space states are expressed with circles. In the state transition diagram, 00 is valid state 1, A1 corresponds to valid state 2, B1 corresponds to valid state 3, Cl to C3 correspond to valid states 4 to 6, B2 is valid state 7, C5 to C6 correspond to valid states 8 to 9, B3 is valid state 10, C8 to C10 correspond to valid states 11 to 13, A2 corresponds to valid state 14, B5 corresponds to valid state 15, C12 to C14 correspond to valid states 16 to 18, B6 is valid state 19, C16 to C18 correspond to valid states 20 to 22, B7 is valid state 23, C20 to C22 correspond to valid states 24 to 26, B8 is valid state 27, C24 to C27 correspond to valid states 28 to 31, A3 corresponds to valid state 32, B10 corresponds to valid state 33, C29 to C30 correspond to valid states 34 to 35, B11 corresponds to valid state 36, C32 to C34 correspond to valid states 37 to 39, B12 corresponds to valid state 40, C36 to C38 correspond to valid states 41 to 43, A4 corresponds to valid state 44, B14 corresponds to valid state 45, C40 to C42 correspond to valid states 46 to 48, B15 is valid state 49, C44 to C47 correspond to valid states 50 to 53, B16 is valid state 54, C49 to C51 correspond to valid states 55 to 57, B17 is valid state 58, and C53 to C56 correspond to valid states 59 to 62. Other states A5, B4, B9, B13, B18, C4, C7, C11, C15, C19, C23, C28, C31, C35, C39, C43, C48, C52, C57 and F in the state transition diagram are all invalid states.

The symbols and meanings of first-level and second-level Markov space states in FIG. 1 are shown in Table 20.

TABLE 20
Symbols of first-level and second-level Markov space states

| State | |
|---|---|
| Symbol | Meaning |
| 00 | Normal State |
| A1 | Capacitor Open-circuit Valid |
| | Operating State |
| A2 | Turn-to-turn Short-circuit Valid |
| | Operating State |
| A3 | Default Phase Valid Operating State |
| A4 | Down MOSFET Short-circuit Valid |
| | Operating State |
| A5 | Invalid State under First-level Fault |
| B1 | Second-level Turn-to-turn Short- |
| | circuit Fault State 1 |
| B2 | Second-level Default Phase State 1 |
| B3 | Second-level Down MOSFET Short- |
| | circuit State 1 |
| B4 | Second-level Invalid State 1 |
| B5 | Second-level Capacitor Open-circuit |
| | State 1 |
| B6 | Second-level Turn-to-turn Short- |
| | circuit Fault State 2 |
| B7 | Second-level Default Phase |
| | State 2 |
| B8 | Second-level Down MOSFET |
| | Short-circuit State 2 |
| B9 | Second-level Invalid State 2 |
| B10 | Second-level Capacitor Open- |
| | circuit State 2 |
| B11 | Second-level Turn-to-turn |
| | Short-circuit Fault State 3 |
| B12 | Second-level Down MOSFET |
| | Short-circuit State 3 |
| B13 | Second-level Invalid State 3 |
| B14 | Second-level Capacitor Open- |
| | circuit State 3 |
| B15 | Second-level Turn-to-turn |
| | Short-circuit Fault State 4 |
| B16 | Second-level Default Phase |
| | State 3 |
| B17 | Second-level Down MOSFET |
| | Short-circuit State 4 |
| B18 | Second-level Invalid State 4 |

The symbols and meanings of third-level Markov space states and final invalid states in FIG. 1 are shown in Table 21.

TABLE 21
Symbols of third-level Markov space states

| State | |
|---|---|
| Symbol | Meaning |
| C1 | Third-level Turn-to-turn Short- |
| | circuit Fault State 1 |
| C2 | Third-level Default Phase State 1 |
| C3 | Third-level Down MOSFET |
| | Short-circuit State 1 |
| C4 | Third-level Invalid State 1 |
| C5 | Third-level Turn-to-turn Short- |
| | circuit Fault State 2 |
| C6 | Third-level Down MOSFET |
| | Short-circuit State 2 |
| C7 | Third-level Invalid State 2 |
| C8 | Third-level Turn-to-turn Short- |
| | circuit Fault State 3 |
| C9 | Third-level Default Phase State 2 |
| C10 | Third-level Down MOSFET |
| | Short-circuit State 3 |
| C11 | Third-level Invalid State 3 |
| C12 | Third-level Turn-to-turn Short- |
| | circuit Fault State 4 |
| C13 | Third-level Default Phase State 3 |
| C14 | Third-level Down MOSFET |
| | Short-circuit State 4 |
| C15 | Third-level Invalid State 4 |
| C16 | Third-level Capacitor Open- |
| | circuit State 1 |
| C17 | Third-level Default Phase State 4 |
| C18 | Third-level Down MOSFET |
| | Short-circuit State 5 |
| C19 | Third-level Invalid State 5 |
| C20 | Third-level Capacitor Open- |
| | circuit State 2 |
| C21 | Third-level Turn-to-turn Short- |
| | circuit Fault State 5 |
| C22 | Third-level Down MOSFET |
| | Short-circuit State 6 |
| C23 | Third-level Invalid State 6 |
| C24 | Third-level Capacitor Open- |
| | circuit State 3 |
| C25 | Third-level Turn-to-turn Short- |
| | circuit Fault State 6 |
| C26 | Third-level Default Phase Default |
| | Phase State 5 |
| C27 | Third-level Down MOSFET |
| | Short-circuit State 7 |
| C28 | Third-level Invalid State 7 |
| C29 | Third-level Turn-to-turn Short- |
| | circuit Fault State 7 |
| C30 | Third-level Down MOSFET Short- |
| | circuit State 8 |
| C31 | Third-level Invalid State 8 |
| C32 | Third-level Capacitor Open-circuit |
| | State 4 |
| C33 | Third-level Turn-to-turn Short- |
| | circuit Fault State 8 |
| C34 | Third-level Down MOSFET Short- |
| | circuit State 9 |
| C35 | Third-level Invalid State 9 |
| C36 | Third-level Capacitor Open-circuit |
| | State 5 |
| C37 | Third-level Turn-to-turn Short- |
| | circuit Fault State 9 |
| C38 | Third-level Down MOSFET Short- |
| | circuit State 10 |
| C39 | Third-level Invalid State 10 |
| C40 | Third-level Turn-to-turn Short- |
| | circuit Fault State 10 |
| C41 | Third-level Default Phase State 6 |
| C42 | Third-level Down MOSFET Short- |
| | circuit State 11 |
| C43 | Third-level Invalid State 11 |
| C44 | Third-level Capacitor Open-circuit |
| | State 6 |
| C45 | Third-level Turn-to-turn Short- |
| | circuit Fault State 11 |
| C46 | Third-level Default Phase State 7 |
| C47 | Third-level Down MOSFET Short- |
| | circuit State 12 |
| C48 | Third-level Invalid State 12 |
| C49 | Third-level Capacitor Open-circuit State 7 |
| C50 | Third-level Tum-to-turn Short- |
| | circuit Fault State 12 |
| C51 | Third-level Down MOSFET Short- |
| | circuit State 13 |
| C52 | Third-level Invalid State 13 |
| C53 | Third-level Capacitor Open-circuit |
| | State 8 |
| C54 | Third-level Turn-to-turn Short- |
| | circuit Fault State 13 |
| C55 | Third-level Default Phase State 8 |
| C56 | Third-level Down MOSFET Short- |
| | circuit State 14 |
| C57 | Third-level Invalid State 14 |
| F | Final Invalid State |

Table 22 shows the symbols and calculation formulae of state transition rates under first-level and second-level faults in FIG. 1.

TABLE 22
First-level and second-level state transition rates

| | State | |
|---|---|---|
| No. | Transition Rate | Calculation Formula |
| 1 | λ_{A1}, λ_{B5}, λ_{B10}, λ_{B14} | λ_{A1} = λ_{CO} |
| 2 | λ_{A2}, λ_{B1}, λ_{B15} | λ_{A2} = 0.3λ_{TTS} |
| 3 | λ_{A3}, λ_{B2} | λ_{A3} = 3λ_{DP1} |
| 4 | λ_{A4}, λ_{B3}, λ_{B8} | λ_{A4} = 1.62(λ_{DMS} + λ_{PSS}) |
| 5 | λ_{A5} | λ_{A5} = λ_{SP} + 0.36(λ_{DP} + λ_{DMS} + λ_{PSS}) + |
| | | 2.01λ_{UMS} |
| 6 | λ_{B4} | λ_{B4} = λ_{A5} − λ_{CS} |
| 7 | λ_{B6}, λ_{B11} | λ_{B6} = 0.2λ_{TTS} |
| 8 | λ_{B7} | λ_{B7} = 3λ_{DP1} − 0.9λ_{TTS} |
| 9 | λ_{B9} | λ_{B9} = λ_{SP} + 0.36(λ_{DP} + λ_{DMS}) + |
| | | 1.8λ_{TTS} + 2.01λ_{UMS} |
| 10 | λ_{B12} | λ_{B12} = 0.76(λ_{DMS} + λ_{PPS}) |
| 11 | λ_{B13} | λ_{B13} = λ_{SP} + 2λ_{DP} + 1.24(λ_{DMS} + |
| | | λ_{PSS}) + 1.8λ_{TTS} + 2λ_{UMS} |
| 12 | λ_{B16} | λ_{B16} = 0.88(λ_{DP} − λ_{DMO}) + 1.76λ_{DP} + |
| | | 0.7λ_{UMS} 1.01(λ_{DMS} + λ_{PSS}) + 2.7λ_{TTS} |
| 13 | λ_{B17} | λ_{B17} = 0.9(λ_{DMS} + λ_{PSS}) |
| 14 | λ_{B18} | λ_{B18} = λ_{SP} + 0.36(λ_{DP} − λ_{DMO}) + |
| | | 2.3λ_{UMS} + 0.3λ_{DMS} |

Third-level state transition rates are shown in Table 23.

TABLE 23
Third-level state transition rates

| | State | |
|---|---|---|
| No. | Transition Rate | Calculation Formula |
| 1 | λ_{C1}, λ_{C5}, λ_{C12}, | λ_{C1} = 0.2λ_{TTS} |
| | λ_{C21}, λ_{C25}, λ_{C29}, | |
| | λ_{C33}, λ_{C37}, λ_{C45}, | |
| | λ_{C50}, λ_{C54} | |
| 2 | λ_{C2}, λ_{C13} | λ_{C2} = 3λ_{DP1} − 0.9λ_{TTS} |
| 3 | λ_{C3}, λ_{C14}, λ_{C18} | λ_{C3} = 1.62(λ_{DMS} + λ_{PSS}) |
| 4 | λ_{C4} | λ_{C4} = λ_{SP} − λ_{CS} + 0.36(λ_{DMS} + λ_{PSS} + |
| | | λ_{DP}) + 2.01λ_{UMS} |
| 5 | λ_{C6}, λ_{C27}, λ_{C30}, | λ_{C5} = 0.76(λ_{DMS} + λ_{PSS}) |
| | λ_{C34}, λ_{C38}, λ_{C51}, | |
| | λ_{C56} | |
| 6 | λ_{C7}, λ_{C11}, λ_{C15} | λ_{C7} = λ_{SP} − λ_{CS} + 1.24(λ_{DMS} + λ_{PSS}) + |
| | | 2(λ_{DP} + λ_{UMS}) + 1.8λ_{TTS} |
| 7 | λ_{C8}, λ_{C40} | λ_{C8} = 0.3λ_{TTS} |
| 8 | λ_{C9} | λ_{C9} = 1.68λ_{DP} − 0.88λ_{DMO} + 0.7λ_{UMS} + |
| | | 0.8(λ_{DMS} + λ_{PSS}) |
| 9 | λ_{C10}, λ_{C22}, λ_{C42}, | λ_{C10} = 0.9(λ_{DMS} + λ_{PSS}) |
| | λ_{C47} | |
| 10 | λ_{C16}, λ_{C20}, λ_{C24}, | λ_{C16} = λ_{CO} |
| | λ_{C32}, λ_{C36}, λ_{C44}, | |
| | λ_{C49}, λ_{C53} | |
| 11 | λ_{C17} | λ_{C17} = 3λ_{DP1} − 1.8λ_{TTS} |
| 12 | λ_{C19} | λ_{C19} = λ_{SP} + 0.36(λ_{DMS} + λ_{PSS} + λ_{DP}) + |
| | | 2.01λ_{UMS} + λ_{TTS} |
| 13 | λ_{C23} | λ_{C23} = λ_{SP} + 0.36(λ_{DMS} + λ_{PSS} + λ_{DP}) + |
| | | 2.01λ_{UMS} |
| 14 | λ_{C26}, λ_{C41}, λ_{C55} | λ_{C26} = 2.64λ_{DP} − 0.88λ_{DMO} + 1.8λ_{TTS} + |
| | | 0.7λ_{UMS} + 0.8(λ_{DMS} + λ_{PSS}) |
| 16 | λ_{C28}, λ_{C48} | λ_{C28} = λ_{SP} + 0.36λ_{DP} − 0.12λ_{DMO} + |
| | | 2.3λ_{UMS} + 0.3λ_{DMS} |
| 17 | λ_{C31} | λ_{C31} = λ_{SP1} − λ_{CS} + 1.24λ_{DMS} + 2(λ_{DP} + |
| | | λ_{UMS}) + 1.8λ_{TTS} |
| 18 | λ_{C35}, λ_{C39}, λ_{C52} | λ_{C35} = λ_{SP1} + 0.9 λ_{TTS} + 1.24 λ_{DMS} + 2(λ_{DP} + |
| | | λ_{UMS}) |
| 19 | λ_{C43} | λ_{C43} = λ_{SP} − λ_{CS} + 2.24λ_{UMO} + 0.56λ_{DP} − |
| | | 0.12λ_{DMO} + 2.3λ |
| 20 | λ_{C46} | λ_{C46} = 0.88(3λ_{DP} − λ_{DMO}) + 1.8λ_{TTS} + |
| | | 0.7λ_{UMS} + 0.8λ_{DMS} |
| 21 | λ_{C57} | λ_{C57} = λ_{SP} + 0.24(λ_{DP} − λ_{DMO}) + 0.22λ_{DP} + |
| | | 2.65λ_{UMS} + 0.15λ_{DMS} |

The transition rates from third-level valid states to final states are shown in Table 24.

TABLE 24
Transition rates from third-level valid states to final states

| | State | |
|---|---|---|
| No. | Transition Rate | Calculation Formula |
| 1 | λ_{F1}, λ_{F9}, λ_{F12} | λ_{F1} = λ_{A} − λ_{CS} − λ_{CO} − 2λ_{TTS} − 2λ_{TTO} |
| 2 | λ_{F2}, λ_{F4}, λ_{F10}, | λ_{F2} = λ_{A} − λ_{TTS} − λ_{TTO} − λ_{PH} − λ_{CS} − λ_{CO} |
| | λ_{F15}, λ_{F22}, λ_{F24} | |
| 3 | λ_{F3}, λ_{F6}, λ_{F11}, | λ_{F3} = λ_{A} − λ_{CS} − λ_{CO} − λ_{TTS} − λ_{TTO} − |
| | λ_{F18}, λ_{F30}, λ_{F33} | λ_{DMS} − λ_{DMO} |
| 4 | λ_{F5}, λ_{F7}, λ_{F23}, | λ_{F5} = λ_{A} − λ_{CS} − λ_{CO} − λ_{PH} − λ_{DMS} − |
| | λ_{F27}, λ_{F31}, λ_{F37} | λ_{DMO} |
| 5 | λ_{F8}, λ_{F32}, λ_{F40} | λ_{F8} = λ_{A} − λ_{CS} − λ_{CO} − 2λ_{DMS} − 2λ_{DMO} |
| 6 | λ_{F13}, λ_{F16}, λ_{F25} | λ_{F13} = λ_{A} − 2λ_{TTS} − 2λ_{TTO} − λ_{PH} |
| 7 | λ_{F14}, λ_{F19}, λ_{F34} | λ_{F14} = λ_{A} − 2λ_{TTS} − 2λ_{TTO} − λ_{DMS} − |
| | | λ_{DMO} |
| 8 | λ_{F17}, λ_{F20}, λ_{F26}, | λ_{F17} = λ_{A} − λ_{TTS} − λ_{TTO} − λ_{PH} − λ_{DMS} − |
| | λ_{F28}, λ_{F35}, λ_{F38} | λ_{DMO} |
| 9 | λ_{F21}, λ_{F36}, λ_{F41} | λ_{F21} = λ_{A} − λ_{TTS} − λ_{TTO} − 2λ_{DMS} − 2λ_{DMO} |
| 10 | λ_{F29}, λ_{F39}, λ_{F42} | λ_{F29} = λ_{A} − λ_{PH} − 2λ_{DMS} − 2λ_{DMO} |
| 11 | λ_{F43} | λ_{F43} = λ_{A} − 3λ_{DMS} − 3λ_{DMO} |

The meanings of the symbols in the calculation formulae of Table 22, Table 23 and Table 24 are shown in Table 25.

TABLE 25
Meanings of state transition rate symbols

| Symbol | Meaning | Symbol | Meaning |
|---|---|---|---|
| λ_{CO} | Capacitor Open-circuit Fault | λ_{TTS} | Turn-to-turn Short-circuit Fault |
| | Probability | | Probability |
| λ_{CS} | Capacitor Short-circuit Fault | λ_{TTO} | Turn-to-turn Open-circuit Fault |
| | Probability | | Probability |
| λ_{DMS} | Down MOSFET Short-circuit | λ_{POS} | Pole-to-pole Short-circuit Fault |
| | Fault Probability | | Probability |
| λ_{DMO} | Down MOSFET Open-circuit | λ_{PGS} | Phase-to-ground Short-circuit Fault |
| | Fault Probability | | Probability |
| λ_{UMS} | Upper MOSFET Short-circuit | λ_{PHS} | Phase-to-phase Short-circuit Fault |
| | Fault Probability | | Probability |
| λ_{UMO} | Upper MOSFET Open-circuit | λ_{PSS} | Position Sensor Short-circuit Fault |
| | Fault Probability | | Probability |
| λ_{DDS} | Down Diode Short-circuit Fault | λ_{PSO} | Position Sensor Open-circuit Fault |
| | Probability | | Probability |
| λ_{DDO} | Down Diode Open-circuit Fault | λ_{PH} | One-phase Fault Total Failure |
| | Probability | | Probability |
| λ_{UDS} | Upper Diode Short-circuit Fault | λ_{A} | Fault Probability of All Devices of |
| | Probability | | the System |
| λ_{UDO} | Upper Diode Open-circuit Fault | λ_{DP} | Intrinsic Default Phase Probability |
| | Probability | | |
| λ_{SP1} | System Failure Probability after | λ_{DP1} | Equivalent Default Phase |
| | Default Phase | | Probability |
| λ_{SP} | Intrinsic Failure Probability of | | |
| | the System | | |

The calculation formulae of λ_{DP}, λ_{DP1}, λ_{SP} and λ_{SP1} in the above table are shown below:

λ_{DP}=λ_{UMO}+λ_{DMO}+λ_{UOS}+λ_{DOS}+λ_{TTO}+λ_{PSO}

λ_{DP1}=0.88λ_{DP}+0.34(λ_{DMS}+λ_{PSS})+0.43λ_{UMS}+0.9λ_{TTS}

λ_{SP}=λ_{CS}+3(λ_{UDO}+λ_{DDO}=λ_{POS}+λ_{PGS}+λ_{PHS})

λ_{SP1}=λ_{CS}+2(λ_{UDO}+λ_{DDO}+λ_{POS}+λ_{PGS}+λ_{PHS})

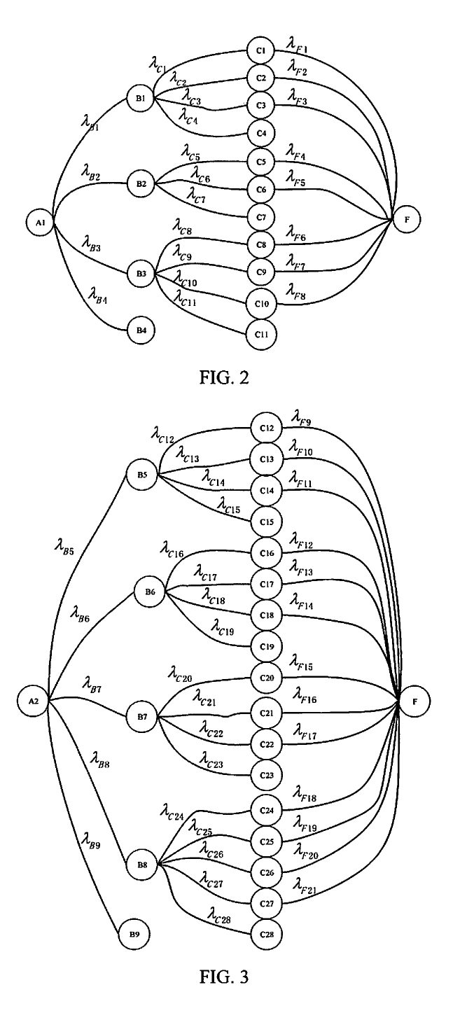

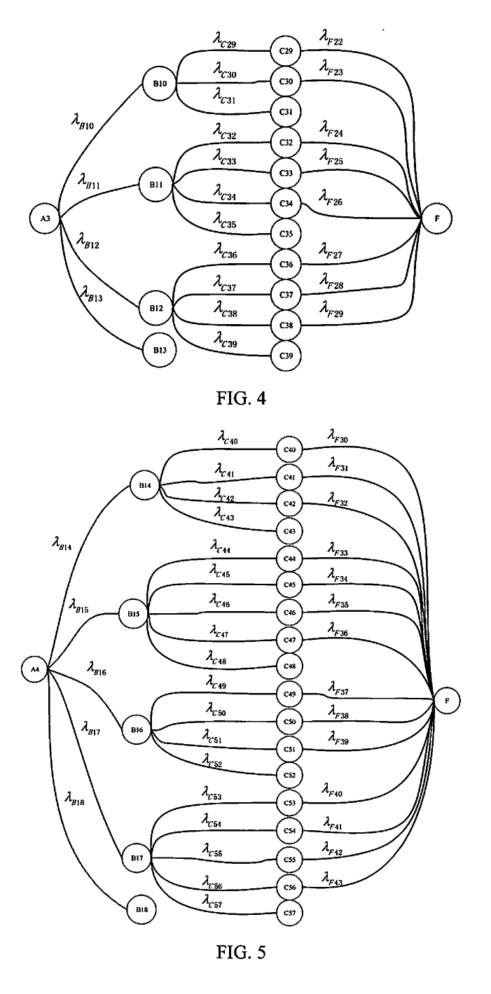

Three-level Markov model consists of four submodels: A1, A2, A3 and A4, as shown in FIG. 2, FIG. 3, FIG. 4 and FIG. 5 respectively.

Reliability is the sum of probabilities in valid states, so quantitative evaluation of reliability may be realized as long as the sum of probabilities in valid states is obtained.

Through analysis of the operating condition of switched reluctance motor drive system under first-level faults, second-level faults and third-level faults, 5 first-level Markov states including 4 valid states and 1 invalid state, 18 second-level Markov states including 14 valid states and 4 invalid states, and 57 third-level Markov states including 43 valid states and 14 invalid states are obtained in total. If initial normal state and final invalid state are also considered, a three-level Markov model will have 62 valid states and 20 invalid states in total. A state transition diagram of the switched reluctance motor drive system under three-level faults is established, and a valid state transition matrix A under three-level faults is obtained:

$$A = [ \begin{matrix}A 1 & A 11 & A 12 & A 13 \\ O & A 2 & O & O \\ O & O & A 3 & O \\ O & O & O & A 4\end{matrix} ] \qquad ( 1 )$$

State transition matrix A is a square matrix with 62 lines and 62 columns. The lines of state transition matrix A stand for initial valid states, the columns of state transition matrix A stand for next states to be transferred, corresponding transition rates are corresponding elements in state transition matrix A, and the transition rate of a state is the opposite number of the transition probability sum of transition from this state to all states (including invalid states). In Formula (1), A1, A11, A12, A13, A2, A3, A4 are nonzero matrices, O stands for zero matrix, and sub-matrix A1 is a square matrix with 13 lines and 13 columns:

$$A 1 = [ \begin{matrix}B 1 & B 21 & B 31 \\ O & B 2 & O \\ O & O & B 3\end{matrix} ] \qquad ( 2 )$$

In Formula (2), B1, B21, B31, B2, B3 are nonzero matrices, O stands for zero matrix, B21 and B31 of the five nonzero matrices have only one nonzero element, the rest elements are all zero elements, and the five sub-matrices are:

$$\begin{matrix}B 1 = [ \begin{matrix}- ( {λ}_{A 1} + {λ}_{A 2} + {λ}_{A 3} + {λ}_{A 4} + {λ}_{A 5} ) & {λ}_{A 1} & 0 & 0 & 0 & 0 \\ 0 & - ( {λ}_{B 1} + {λ}_{B 2} + {λ}_{B 3} + {λ}_{B 4} ) & {λ}_{B 1} & 0 & 0 & 0 \\ 0 & 0 & - ( {λ}_{C 1} + {λ}_{C 2} + {λ}_{C 3} + {λ}_{C 4} ) & {λ}_{C 1} & {λ}_{C 2} & {λ}_{C 3} \\ & 0 & 0 & - {λ}_{F 1} & 0 & 0 \\ & 0 & 0 & 0 & - {λ}_{F 2} & 0 \\ & 0 & 0 & 0 & 0 & - {λ}_{F 3}\end{matrix} ] & ( 3 ) \\ B 2 = [ \begin{matrix}- ( {λ}_{C 5} + {λ}_{C 6} + {λ}_{C 7} ) & {λ}_{C 5} & {λ}_{C 6} \\ 0 & - {λ}_{F 4} & 0 \\ 0 & 0 & - {λ}_{F 5}\end{matrix} ] & ( 4 ) \\ B 3 = [ \begin{matrix}- ( {λ}_{C 8} + {λ}_{C 9} + {λ}_{C 10} + {λ}_{C 11} ) & {λ}_{C 8} & {λ}_{C 9} & {λ}_{C 10} \\ 0 & - {λ}_{F 6} & 0 & 0 \\ 0 & 0 & - {λ}_{F 7} & 0 \\ 0 & 0 & 0 & - {λ}_{F 8}\end{matrix} ] & ( 5 ) \\ B 21 = [ \begin{matrix}0 & 0 & 0 \\ {λ}_{B 2} & 0 & 0 \\ 0 & 0 & 0 \\ 0 & 0 & 0 \\ 0 & 0 & 0 \\ 0 & 0 & 0\end{matrix} ] & ( 6 ) \\ B 31 = [ \begin{matrix}0 & 0 & 0 & 0 \\ {λ}_{B 3} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 7 )\end{matrix}$$

Sub-matrix A2 is a square matrix with 18 lines and 18 columns:

$$A 2 = [ \begin{matrix}B 5 & B 61 & B 71 & B 81 \\ O & B 6 & O & O \\ O & O & B 7 & O \\ O & O & O & B 8\end{matrix} ] \qquad ( 8 )$$

In Formula (8), B5, B61, B71, B81, B6, B7, B8 are nonzero matrices, O stands for zero matrix, B61, B71 and B81 of the seven nonzero matrices have only one nonzero element, the rest elements are all zero elements, and the seven sub-matrices are:

$$\begin{matrix}B 5 = [ \begin{matrix}- ( {λ}_{B 5} + {λ}_{B 6} + {λ}_{B 7} + {λ}_{B 8} + {λ}_{B 9} ) & {λ}_{B 5} & 0 & 0 & 0 \\ 0 & \begin{matrix}- ( {λ}_{C 12} + {λ}_{C 13} + {λ}_{C 14} + {λ}_{C 15} ) \\ □\end{matrix} & {λ}_{C 12} & {λ}_{C 13} & {λ}_{C 14} \\ 0 & 0 & - {λ}_{F 9} & 0 & 0 \\ 0 & 0 & 0 & - {λ}_{F 10} & 0 \\ 0 & 0 & 0 & 0 & - {λ}_{F 11}\end{matrix} ] & ( 9 ) \\ B 6 = [ \begin{matrix}- ( {λ}_{C 16} + {λ}_{C 17} + {λ}_{C 18} + {λ}_{C 19} ) & {λ}_{C 16} & {λ}_{C 17} & {λ}_{C 18} \\ 0 & - {λ}_{F 12} & 0 & 0 \\ 0 & 0 & - {λ}_{F 13} & 0 \\ 0 & 0 & 0 & - {λ}_{F 14}\end{matrix} ] & ( 10 ) \\ B 7 = [ \begin{matrix}- ( {λ}_{C 20} + {λ}_{C 21} + {λ}_{C 22} + {λ}_{C 23} ) & {λ}_{C 20} & {λ}_{C 21} & {λ}_{C 22} \\ 0 & - {λ}_{F 15} & 0 & 0 \\ 0 & 0 & - {λ}_{F 16} & 0 \\ 0 & 0 & 0 & - {λ}_{F 17}\end{matrix} ] & ( 11 ) \\ B 8 = [ \begin{matrix}- ( {λ}_{C 24} + {λ}_{C 25} + {λ}_{C 26} + {λ}_{C 27} + {λ}_{C 28} ) & {λ}_{C 24} & {λ}_{C 25} & {λ}_{C 26} & {λ}_{C 27} \\ 0 & - {λ}_{F 18} & 0 & 0 & 0 \\ 0 & 0 & - {λ}_{F 19} & 0 & 0 \\ 0 & 0 & 0 & - {λ}_{F 20} & 0 \\ 0 & 0 & 0 & 0 & - {λ}_{F 21}\end{matrix} ] & ( 12 ) \\ B 61 = [ \begin{matrix}{λ}_{B 6} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 13 ) \\ B 71 = [ \begin{matrix}{λ}_{B 7} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 14 ) \\ B 81 = [ \begin{matrix}{λ}_{B 8} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 15 )\end{matrix}$$

Sub-matrix A3 is a square matrix with 12 lines and 12 columns:

$$A 3 = [ \begin{matrix}B 10 & B 111 & B 121 \\ O & B 11 & O \\ 0 & O & B 12\end{matrix} ] \qquad ( 16 )$$

In Formula (16), B10, B111, B121, B11, B12 are nonzero matrices, O stands for zero matrix, B111 and B121 of the five nonzero matrices have only one nonzero element, the rest elements are all zero elements, and the five sub-matrices are:

$$\begin{matrix}B 10 = [ \begin{matrix}- ( {λ}_{B 10} + {λ}_{B 11} + {λ}_{B 12} + {λ}_{B 13} ) & {λ}_{B 10} & 0 & 0 \\ 0 & - ( {λ}_{C 29} + {λ}_{C 30} + {λ}_{C 31} ) & {λ}_{C 29} & {λ}_{C 30} \\ 0 & 0 & - {λ}_{F 22} & 0 \\ 0 & 0 & 0 & - {λ}_{F 23}\end{matrix} ] & ( 17 ) \\ B 11 = [ \begin{matrix}- ( {λ}_{C 32} + {λ}_{C 33} + {λ}_{C 34} + {λ}_{C 35} ) & {λ}_{C 32} & {λ}_{C 33} & {λ}_{C 34} \\ 0 & - {λ}_{F 24} & 0 & 0 \\ 0 & 0 & - {λ}_{F 25} & 0 \\ 0 & 0 & 0 & - {λ}_{F 26}\end{matrix} ] & ( 18 ) \\ B 12 = [ \begin{matrix}- ( {λ}_{C 36} + {λ}_{C 37} + {λ}_{C 38} + {λ}_{C 39} ) & {λ}_{C 36} & {λ}_{C 37} & {λ}_{C 38} \\ 0 & - {λ}_{F 27} & 0 & 0 \\ 0 & 0 & - {λ}_{F 28} & 0 \\ 0 & 0 & 0 & - {λ}_{F 29}\end{matrix} ] & ( 19 ) \\ B 111 = [ \begin{matrix}{λ}_{B 11} & 0 & 0 & 0 \\ 0 & 0 & 0 & 0 \\ 0 & 0 & 0 & 0 \\ 0 & 0 & 0 & 0\end{matrix} ] & ( 20 ) \\ B 121 = [ \begin{matrix}{λ}_{B 12} & 0 & 0 & 0 \\ 0 & 0 & 0 & 0 \\ 0 & 0 & 0 & 0 \\ 0 & 0 & 0 & 0\end{matrix} ] & ( 21 )\end{matrix}$$

Sub-matrix A4 is a square matrix with 19 lines and 19 columns:

$$A 4 = [ \begin{matrix}B 14 & B 151 & B 161 & B 171 \\ O & B 15 & O & O \\ O & O & B 16 & O \\ O & O & O & B 17\end{matrix} ] \qquad ( 22 )$$

In Formula (22), B14, B151, B161, B171, B15, B16, B17 are nonzero matrices, O stands for zero matrix, B151, B161 and B171 of the seven nonzero matrices have only one nonzero element, the rest elements are all zero elements, and the seven sub-matrices are:

$$\begin{matrix}B 14 = [ \begin{matrix}- ( {λ}_{B 14} + {λ}_{B 15} + {λ}_{B 16} + {λ}_{B 17} + {λ}_{B 18} ) & {λ}_{B 14} & 0 & 0 & 0 \\ 0 & - ( {λ}_{C 40} + {λ}_{C 41} + {λ}_{C 42} + {λ}_{C 43} ) & {λ}_{C 40} & {λ}_{C 41} & {λ}_{C 42} \\ 0 & 0 & - {λ}_{F 30} & 0 & 0 \\ 0 & 0 & 0 & - {λ}_{F 31} & 0 \\ 0 & 0 & 0 & 0 & - {λ}_{F 32}\end{matrix} ] & ( 23 ) \\ B 15 = [ \begin{matrix}- ( {λ}_{C 44} + {λ}_{C 45} + {λ}_{C 46} + {λ}_{C 47} + {λ}_{C 48} ) & {λ}_{C 44} & {λ}_{C 45} & {λ}_{C 46} & {λ}_{C 47} \\ 0 & - {λ}_{F 33} & 0 & 0 & 0 \\ 0 & 0 & - {λ}_{F 34} & 0 & 0 \\ 0 & 0 & 0 & - {λ}_{F 35} & 0 \\ 0 & 0 & 0 & 0 & - {λ}_{F 36}\end{matrix} ] & ( 24 ) \\ B 16 = [ \begin{matrix}- ( {λ}_{C 49} + {λ}_{C 50} + {λ}_{C 51} + {λ}_{C 52} ) & {λ}_{C 49} & {λ}_{C 50} & {λ}_{C 51} \\ 0 & - {λ}_{F 37} & 0 & 0 \\ 0 & 0 & - {λ}_{F 38} & 0 \\ 0 & 0 & 0 & - {λ}_{F 39}\end{matrix} ] & ( 25 ) \\ B 17 = [ \begin{matrix}- ( {λ}_{C 53} + {λ}_{C 54} + {λ}_{C 55} + {λ}_{C 56} + {λ}_{C 57} ) & {λ}_{C 53} & {λ}_{C 54} & {λ}_{C 55} & {λ}_{C 56} \\ 0 & - {λ}_{F 40} & 0 & 0 & 0 \\ 0 & 0 & - {λ}_{F 41} & 0 & 0 \\ 0 & 0 & 0 & - {λ}_{F 42} & 0 \\ 0 & 0 & 0 & 0 & - {λ}_{F 43}\end{matrix} ] & ( 26 ) \\ B 151 = [ \begin{matrix}{λ}_{B 15} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 27 ) \\ B 161 = [ \begin{matrix}{λ}_{B 16} & 0 & 0 & 0 \\ 0 & 0 & 0 & 0 \\ 0 & 0 & 0 & 0 \\ 0 & 0 & 0 & 0\end{matrix} ] & ( 28 ) \\ B 171 = [ \begin{matrix}{λ}_{B 17} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 29 )\end{matrix}$$

In the formulae, λ_{A1}, λ_{A2}, λ_{A3}, λ_{A4}, λ_{A5}, λ_{B1}, λ_{B2}, λ_{B3}, λ_{B4}, λ_{B5}, λ_{B6}, λ_{B7}, λ_{B8}, λ_{B9}, λ_{B10}, λ_{B11}, λ_{B12}, λ_{B13}, λ_{B14}, λ_{B15}, λ_{B16}, λ_{B17}, λ_{B18}, λ_{C1}, λ_{C2}, λ_{C3}, λ_{C4}, λ_{C5}, λ_{C6}, λ_{C7}, λ_{C8}, λ_{C9}, λ_{C10}, λ_{C11}, λ_{C12}, λ_{C13}, λ_{C14}, λ_{C15}, λ_{C16}, λC_{C17}, λ_{C18}, λC_{C19}, λC_{C20}, λC_{C21}, λC_{C22}, λC_{C23}, λC_{C24}, λC_{C25}, λC_{C26}, λC_{C27}, λC_{C28}, λC_{C29}, λC_{C30}, λC_{C31}, λC_{C32}, λC_{C33}, λC_{C34}, λC_{C35}, λC_{C36}, λC_{C37}, λC_{C38}, λC_{C39}, λC_{C40}, λC_{C41}, λC_{C42}, λC_{C43}, λC_{C44}, λC_{C45}, λC_{C46}, λC_{C47}, λC_{C48}, λC_{C49}, λC_{C50}, λC_{C51}, λC_{C52}, λC_{C53}, λC_{C54}, λ_{C55}, λC_{C56}, λC_{C57}, λC_{F1}, λC_{F2}, λC_{F3}, λC_{F4}, λC_{F5}, λC_{F6}, λC_{F7}, λC_{F8}, λC_{F9}, λC_{F10}, λC_{F11}, λC_{F12}, λC_{F13}, C_{F14}, λC_{F15}, λC_{F16}, λC_{F17}, λC_{F18}, λC_{F19}, λC_{F20}, λC_{F21}, λC_{F22}, λC_{F23}, λC_{F2}, λC_{F25}, λC_{F26}, λC_{F27}, λC_{F28}, λ_{F29}, λC_{F30}, λC_{F31}, λC_{F32}, λC_{F33}, λC_{F34}, λC_{F35}, λC_{F36}, λC_{F37}, λC_{F38}, λC_{F39}, λC_{F40}, λC_{F41}, λC_{F42}, λC_{F43} are state transition rates of a three-level Markov model;

By using Formula:

$$P ( T ) \cdot A = \frac{dP ( T )}{dt} \qquad ( 30 )$$

The probability matrix P(t) of the switched reluctance motor system in valid states is attained:

$$P ( t ) = [ \begin{matrix}{P}_{A 1} ( t ) \\ {P}_{A 2} ( t ) \\ {P}_{A 3} ( t ) \\ {P}_{A 4} ( t )\end{matrix} ] \qquad ( 31 )$$

In Formula (31), P_{A1}(t), P_{A2}(t), P_{A3}(t) and P_{A4}(t) denote valid-state probabilities in A1 submodel, A2 submodel, A3 submodel and A4 submodel, as shown in Formulae (32) to (35):

$$\begin{matrix}{P}_{A 1} ( t ) = [ \begin{matrix}exp ( - 4.81 t ) \\ 0.0686 exp ( - 2.99 t ) - 0.0686 exp ( - 4.81 t ) \\ 0.0202 exp ( - 2.95 t ) - 0.0206 exp ( - 2.99 t ) \\ 0.0128 exp ( - 1.54 t ) - 0.023 exp ( - 2.99 t ) + 0.0103 exp ( - 4.81 t ) \\ 0.0246 exp ( - 0.237 t ) - 0.06 exp ( - 2.99 t ) + 0.0374 exp ( - 4.81 t ) \\ 1.04 e - 4 exp ( - 2.95 t ) + 1.34 e - 5 exp ( - 4.43 t ) \\ 0.0516 exp ( - 2.99 t ) - 0.0525 exp ( - 2.95 t ) + 0.00134 exp ( - 2.01 t ) \\ 0.009 exp ( - 2.95 t ) - 0.009 exp ( - 2.99 t ) + 7.97 e - 4 exp ( - 4.04 t ) \\ 8.85 e - 4 exp ( - 3.67 t ) - 6.9 e - 4 exp ( - 2.99 t ) - 2.5 e - 4 exp ( - 4.81 t ) \\ 0.001 exp ( - 0.237 t ) - 0.013 exp ( - 2.99 t ) + 0.02 exp ( - 4.07 t ) \\ 3.48 e - 4 exp ( - 3.96 t ) - 1.37 e - 4 exp ( - 4.81 t ) \\ 0.145 exp ( - 3.19 t ) + 0.009 exp ( - 1.54 t ) - 0.147 exp ( - 2.99 t ) \\ 0.0103 exp ( - 3.64 t ) - 0.009 exp ( - 2.99 t ) - 0.002 exp ( - 4.81 t )\end{matrix} ] & ( 32 ) \\ {P}_{A 2} ( t ) = [ \begin{matrix}0.0659 exp ( - 3.08 t ) - 0.00659 exp ( - 4.81 t ) \\ 0.006 exp ( - 2.96 t ) - 0.006 exp ( - 3.08 t ) + 4.43 e - 4 exp ( - 4.81 t ) \\ 0.001 exp ( - 3.04 t ) - 0.001 exp ( - 3.08 t ) \\ 0.002 exp ( - 0.404 t ) - 0.006 exp ( - 3.08 t ) + 0.004 exp ( - 4.81 t ) \\ 0.001 exp ( - 1.83 t ) - 0.002 exp ( - 3.08 t ) + 0.00108 exp ( - 4.81 t ) \\ 3.57 e - 5 exp ( - 2.96 t ) - 4.23 e - 5 exp ( - 3.08 t ) + 1.28 e - 5 exp ( - 4.27 t ) \\ 0.00976 exp ( - 3.5 t ) - 0.0342 exp ( - 3.08 t ) + 0.0253 exp ( - 2.96 t ) \\ 1.19 e - 4 exp ( - 3.04 t ) + 1.36 e - 5 exp ( - 4.27 t ) \\ 4.24 e - 4 exp ( - 3.74 t ) - 0.00441 exp ( - 3.08 t ) + 0.00405 exp ( - 3.04 t ) \\ 5.2 e - 4 exp ( - 3.04 t ) - 5.53 e - 4 exp ( - 3.08 t ) + 5.41 e - 5 exp ( - 4.14 t ) \\ 0.00186 exp ( - 3.55 t ) + 9.4 e - 5 exp ( - 0.404 t ) - 0.00159 exp ( - 3.08 t ) \\ 9.03 e - 5 exp ( - 3.74 t ) - 2.61 e - 5 exp ( - 4.81 t ) \\ 0.00523 exp ( - 3.43 t ) - 0.00472 exp ( - 3.08 t ) - 7.24 e - 4 exp ( - 4.81 t ) \\ 4.36 e - 4 exp ( - 3.96 t ) + 8.72 e - 5 exp ( - 1.83 t ) - 3.66 e - 4 exp ( - 3.08 t ) \\ 4.88 e - 6 exp ( - 1.83 t ) + 2.58 e - 5 exp ( - 4.14 t ) \\ 0.00608 exp ( - 3.73 t ) + 0.00114 exp ( - 1.83 t ) - 0.00575 exp ( - 3.08 t ) \\ 8.7 e - 4 exp ( - 3.83 t ) - 7.88 e - 4 exp ( - 3.08 t ) - 2.53 e - 4 exp ( - 4.81 t ) \\ 6.48 e - 4 exp ( - 0.237 t ) - 7.37 e - 4 exp ( - 0.476 t ) + 1.84 e - 4 exp ( - 3.55 t )\end{matrix} ] & ( 33 ) \\ {P}_{A 3} ( t ) = [ \begin{matrix}0.575 exp ( - 0.476 t ) - 0.575 exp ( - 4.81 t ) \\ 0.284 exp ( - 0.237 t ) - 0.299 exp ( - 0.476 t ) + 0.015 exp ( - 4.81 t ) \\ 0.037 exp ( - 0.36 t ) - 0.038 exp ( - 0.476 t ) \\ 1.72 exp ( - 0.364 t ) - 1.77 exp ( - 0.476 t ) + 0.0445 exp ( - 4.81 t ) \\ 0.0216 exp ( - 0.237 t ) - 0.0248 exp ( - 0.476 t ) + 0.00547 exp ( - 3.24 t ) \\ 0.00115 exp ( - 0.361 t ) - 0.00121 exp ( - 0.476 t ) + 3.54 e - 4 exp ( - 4.39 t ) \\ 6.67 e - 5 exp ( - 0.361 t ) - 7.04 e - 5 exp ( - 0.476 t ) + 3.48 e - 5 exp ( - 4.57 t ) \\ 0.00218 exp ( - 0.361 t ) - 0.00231 exp ( - 0.476 t ) + 5.35 e - 4 exp ( - 4.26 t ) \\ 0.0578 exp ( - 0.364 t ) + 0.00756 exp ( - 4.81 t ) + 0.0109 exp ( - 4.07 t ) \\ 0.0184 exp ( - 3.95 t ) - 0.117 exp ( - 0.476 t ) + 0.11 exp ( - 0.364 t ) \\ 0.00335 exp ( - 0.364 t ) - 0.00354 exp ( - 0.476 t ) + 8.03 e - 4 exp ( - 4.26 t ) \\ 0.00307 exp ( - 3.96 t ) - 1.45 e - 4 exp ( - 1.82 t ) - 0.005 exp ( - 4.38 t ) \\ 3.93 exp ( - 4.38 t ) - 4.55 exp ( - 4.81 t ) \\ 0.0259 exp ( - 1.73 t ) + 0.159 exp ( - 4.81 t ) - 0.18 exp ( - 4.38 t ) \\ 0.002 exp ( - 1.82 t ) + 0.014 exp ( - 4.81 t ) - 0.017 exp ( - 4.38 t ) \\ 0.137 exp ( - 0.364 t ) + 1.28 exp ( - 4.81 t ) - 1.42 exp ( - 4.38 t ) \\ 0.056 exp ( - 1.72 t ) + 0.346 exp ( - 4.81 t ) - 0.402 exp ( - 4.38 t ) \\ 1.32 e - 4 exp ( - 1.73 t ) - 0.00299 exp ( - 3.96 t ) + 0.00497 exp ( - 4.38 t ) \\ 0.0248 exp ( - 1.73 t ) - 0.114 exp ( - 3.24 t ) + 0.236 exp ( - 4.38 t ) \\ 0.00367 exp ( - 1.73 t ) - 0.035 exp ( - 3.64 t ) - 0.0371 exp ( - 4.81 t ) \\ 5.47 e - 4 exp ( - 4.38 t ) - 3.88 e - 4 exp ( - 4.14 t )\end{matrix} ] & ( 34 ) \\ {P}_{A 4} ( t ) = [ \begin{matrix}0.00183 exp ( - 1.82 t ) - 0.0194 exp ( - 4.81 t ) + 0.0379 exp ( - 4.38 t ) \\ 0.00476 exp ( - 3.83 t ) - 0.00409 exp ( - 4.81 t ) + 0.00851 exp ( - 4.38 t ) \\ 0.0595 exp ( - 3.24 t ) - 0.102 exp ( - 4.81 t ) + 0.155 exp ( - 4.38 t ) \\ 0.0046 exp ( - 3.42 t ) - 0.00702 exp ( - 4.81 t ) + 0.0113 exp ( - 4.38 t ) \\ 0.0115 exp ( - 0.364 t ) - 0.0952 exp ( - 3.11 t ) + 0.257 exp ( - 4.38 t ) \\ 0.00405 exp ( - 1.72 t ) - 0.0315 exp ( - 4.81 t ) + 0.0535 exp ( - 4.38 t ) \\ 0.0103 exp ( - 3.64 t ) + 0.001 exp ( - 1.54 t ) = 0.009 exp ( - 2.99 t ) \\ 0.00607 exp ( - 4.38 t ) - 0.00308 exp ( - 3.63 t ) - 0.00332 exp ( - 4.8 t ) \\ 0.0547 exp ( - 1.72 t ) - 0.245 exp ( - 3.22 t ) + 0.51 exp ( - 4.38 t ) \\ 0.044 exp ( - 4.38 t ) - 0.0211 exp ( - 3.32 t ) - 0.027 exp ( - 4.81 t )\end{matrix} ] & ( 35 )\end{matrix}$$

In Formulae (32) to (35), exp denotes an exponential function and t denotes time.

The sum of all elements of probability matrix P(t) in valid states is calculated with Formula (31) to obtain reliability function R(t) of the switched reluctance motor system:

$$R ( t ) = 0.0018 exp ( - 3.96 t ) + 0.0184 exp ( - 3.95 t ) + 8.7 e - 4 exp ( - 3.83 t ) - 0.004 exp ( - 3.83 t ) - 1.74 exp ( - 0.476 t ) + 0.332 exp ( - 0.237 t ) + 5.14 e - 4 exp ( - 3.74 t ) - 0.0142 exp ( - 3.73 t ) + 8.85 e - 4 exp ( - 3.67 t ) + 0.0029 exp ( - 1.83 t ) + 0.01 exp ( - 3.64 t ) - 0.035 exp ( - 3.64 t ) + 0.004 exp ( - 1.82 t ) - 0.003 exp ( - 3.63 t ) - 0.011 exp ( - 3.55 t ) + 0.0544 exp ( - 1.73 t ) - 0.026 exp ( - 3.44 t ) + 0.119 exp ( - 1.72 t ) + 0.005 exp ( - 3.43 t ) - 0.0046 exp ( - 3.42 t ) - 0.0211 exp ( - 3.32 t ) - 0.108 exp ( - 3.24 t ) - 0.0595 exp ( - 3.24 t ) + 0.00269 exp ( - 0.404 t ) - 0.245 exp ( - 3.22 t ) + 0.145 exp ( - 3.19 t ) - 0.0952 exp ( - 3.11 t ) - 0.0662 exp ( - 3.08 t ) + 0.024 exp ( - 1.54 t ) + 0.005 exp ( - 3.04 t ) - 0.166 exp ( - 2.99 t ) + 0.0345 exp ( - 2.96 t ) - 0.0231 exp ( - 2.95 t ) + 2.05 exp ( - 0.364 t ) + 0.04 exp ( - 0.36 t ) - 2.59 exp ( - 4.81 t ) + 3.48 e - 5 exp ( - 4.57 t ) + 1.34 e - 5 exp ( - 4.43 t ) + 3.54 e - 4 exp ( - 4.39 t ) + 3.3 exp ( - 4.38 t ) + 1.28 e - 5 exp ( - 4.27 t ) + 1.36 e - 5 exp ( - 4.27 t ) + 0.0013 exp ( - 4.26 t ) - 3.08 e - 4 exp ( - 4.14 t ) + 0.01 exp ( - 4.07 t ) + 0.023 exp ( - 4.07 t ) + 7.97 e - 4 exp ( - 4.04 ) + 0.001 exp ( - 2.01 t ) \qquad ( 36 )$$

From reliability function R(t), MTTF of the switched reluctance motor system is calculated:

$$MTIF = {\int }_{0}^{∞} R ( t ) dt \qquad ( 37 )$$

Thereby, evaluation of switched reluctance motor system reliability is realized through quantitative analysis of three-level Markov model.

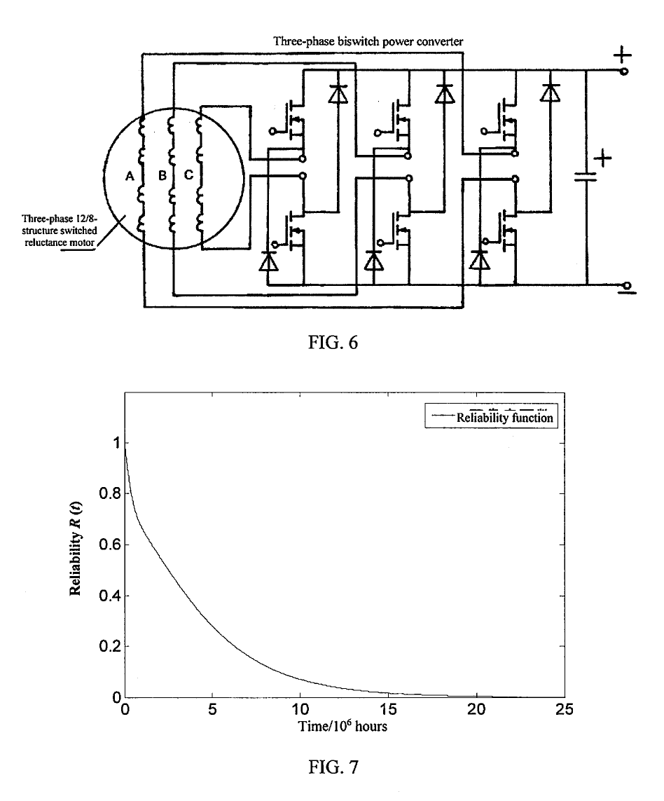

For example, for a switched reluctance motor system comprising a three-phase 12/8-structure switched reluctance motor and a three-phase biswitch power converter, as shown in FIG. 6, through a Markov state transition diagram of the switched reluctance motor system under three-level faults as shown in FIG. 1, a state transition matrix A under three-level faults is established, the probability matrix P(t) of the switched reluctance motor system in valid states is attained, the sum of all elements of probability matrix P(t) in valid states is calculated and reliability function R(t) of the switched reluctance motor system is obtained. As shown in FIG. 7, reliability function curve R(t) is integrated in a time domain from 0 to infinity. Through calculation, it can be obtained that the MTTF of this three-phase switched reluctance motor system is 3637112 hours, thereby realizing quantitative evaluation of reliability of this three-phase switched reluctance motor system through a three-level Markov model. MTTF reflects the area enclosed by reliability function curve R(t), horizontal axis and vertical axis in the first quadrant. The larger the area is, the more reliable the system will be.

1. A method for evaluation of switched reluctance motor system reliability through quantitative analysis of a three-level Markov model, comprising the following steps:
through analyzing the operating condition of switched reluctance motor drive system under first-level faults, second-level faults and third-level faults, 5 first-level Markov states including 4 valid states and 1 invalid state, 18 second-level Markov states including 14 valid states and 4 invalid states, and 57 third-level Markov states including 43 valid states and 14 invalid states are obtained in total; if initial normal state and final invalid state are also considered, a three-level Markov model will have 62 valid states and 20 invalid states in total, a state transition diagram of the switched reluctance motor drive system under three-level faults is established and a valid-state transition matrix A under three-level faults is obtained:
$$A = [ \begin{matrix}A 1 & A 11 & A 12 & A 13 \\ O & A 2 & O & O \\ O & O & A 3 & O \\ O & O & O & A 4\end{matrix} ] \qquad ( 1 )$$
state transition matrix A is a square matrix with 62 lines and 62 columns, the lines of state transition matrix A stand for initial valid states, the columns of state transition matrix A stand for next states to be transferred, corresponding transition rates are corresponding elements in state transition matrix A, and the transition rate of a state is the opposite number of the transition probability sum of the transition from this state to all states (including invalid states); in Formula (1), A1, A11, A12, A13, A2, A3, A4 are nonzero matrices, O stands for zero matrix, and sub-matrix A1 is a square matrix with 13 lines and 13 columns:
$$A 1 = [ \begin{matrix}B 1 & B 21 & B 31 \\ O & B 2 & O \\ O & O & B 3\end{matrix} ] \qquad ( 2 )$$
in Formula (2), B1, B21, B31, B2, B3 are nonzero matrices, O stands for zero matrix, B21 and B31 of the five nonzero matrices have only one nonzero element, the rest elements are all zero elements, and the five sub-matrices are:
$$\begin{matrix}B 1 = [ \begin{matrix}\begin{matrix}- ( {λ}_{A 1} + {λ}_{A 2} + \\ {λ}_{A 3} + {λ}_{A 4} + {λ}_{A 5} )\end{matrix} & {λ}_{A 1} & 0 & 0 & 0 & 0 \\ 0 & \begin{matrix}- ( {λ}_{B 1} + {λ}_{B 2} + \\ {λ}_{B 3} + {λ}_{B 4} )\end{matrix} & {λ}_{B 1} & 0 & 0 & 0 \\ 0 & 0 & \begin{matrix}- ( {λ}_{C 1} + {λ}_{C 2} + \\ {λ}_{C 3} + {λ}_{C 4} )\end{matrix} & {λ}_{C 1} & {λ}_{C 2} & {λ}_{C 3} \\ & 0 & 0 & - {λ}_{F 1} & 0 & 0 \\ & 0 & 0 & 0 & - {λ}_{F 2} & 0 \\ & 0 & 0 & 0 & 0 & - {λ}_{F 3}\end{matrix} ] & ( 3 ) \\ B 2 = [ \begin{matrix}- ( {λ}_{C 5} + {λ}_{C 6} + {λ}_{C 7} ) & {λ}_{C 5} & {λ}_{C 6} \\ 0 & - {λ}_{F 4} & 0 \\ 0 & 0 & - {λ}_{F 5}\end{matrix} ] & ( 4 ) \\ B 3 = [ \begin{matrix}- ( {λ}_{C 8} + {λ}_{C 9} + {λ}_{C 10} + {λ}_{C 11} ) & {λ}_{C 8} & {λ}_{C 9} & {λ}_{C 10} \\ 0 & - {λ}_{F 6} & 0 & 0 \\ 0 & 0 & - {λ}_{F 7} & 0 \\ 0 & 0 & 0 & - {λ}_{F 8}\end{matrix} ] & ( 5 ) \\ B 21 = [ \begin{matrix}0 & 0 & 0 \\ {λ}_{B 2} & 0 & 0 \\ 0 & 0 & 0 \\ 0 & 0 & 0 \\ 0 & 0 & 0 \\ 0 & 0 & 0\end{matrix} ] & ( 6 ) \\ B 31 = [ \begin{matrix}0 & 0 & 0 & 0 \\ {λ}_{B 3} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 7 )\end{matrix}$$
sub-matrix A2 is a square matrix with 18 lines and 18 columns:
$$A 2 = [ \begin{matrix}B 5 & B 61 & B 71 & B 81 \\ O & B 6 & O & O \\ O & O & B 7 & O \\ O & O & O & B 8\end{matrix} ] \qquad ( 8 )$$
in Formula (8), B5, B61, B71, B81, B6, B7, B8 are nonzero matrices, O stands for zero matrix, B61, B71 and B81 of the seven nonzero matrices have only one nonzero element, the rest elements are all zero elements, and the seven sub-matrices are:
$$\begin{matrix}B 5 = [ \begin{matrix}\begin{matrix}- ( {λ}_{B 5} + {λ}_{B 6} + \\ {λ}_{B 7} + {λ}_{B 8} + {λ}_{B 9} )\end{matrix} & {λ}_{B 5} & 0 & 0 & 0 \\ 0 & \begin{matrix}- ( {λ}_{C 12} + {λ}_{C 13} + \\ {λ}_{C 14} + {λ}_{C 15} )\end{matrix} & {λ}_{C 12} & {λ}_{C 13} & {λ}_{C 14} \\ 0 & 0 & - {λ}_{F 9} & 0 & 0 \\ 0 & 0 & 0 & - {λ}_{F 10} & 0 \\ 0 & 0 & 0 & 0 & - {λ}_{F 11}\end{matrix} ] & ( 9 ) \\ B 6 = [ \begin{matrix}- ( {λ}_{C 16} + {λ}_{C 17} + {λ}_{C 18} + {λ}_{C 19} ) & {λ}_{C 16} & {λ}_{C 17} & {λ}_{C 18} \\ 0 & - {λ}_{F 12} & 0 & 0 \\ 0 & 0 & - {λ}_{F 13} & 0 \\ 0 & 0 & 0 & - {λ}_{F 14}\end{matrix} ] & ( 10 ) \\ B 7 = [ \begin{matrix}- ( {λ}_{C 20} + {λ}_{C 21} + {λ}_{C 22} + {λ}_{C 22} ) & {λ}_{C 20} & {λ}_{C 21} & {λ}_{C 22} \\ 0 & - {λ}_{F 15} & 0 & 0 \\ 0 & 0 & - {λ}_{F 16} & 0 \\ 0 & 0 & 0 & - {λ}_{F 17}\end{matrix} ] & ( 11 ) \\ B 8 = [ \begin{matrix}- ( {λ}_{C 24} + {λ}_{C 25} + {λ}_{C 26} + {λ}_{C 27} + {λ}_{C 28} ) & {λ}_{C 24} & {λ}_{C 25} & {λ}_{C 26} & {λ}_{C 27} \\ 0 & - {λ}_{F 18} & 0 & 0 & 0 \\ 0 & 0 & - {λ}_{F 19} & 0 & 0 \\ 0 & 0 & 0 & - {λ}_{F 20} & 0 \\ 0 & 0 & 0 & 0 & - {λ}_{F 21}\end{matrix} ] & ( 12 ) \\ B 61 = [ \begin{matrix}{λ}_{B 6} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 13 ) \\ B 71 = [ \begin{matrix}{λ}_{B 7} & 0 & 0 & 0 \\ 0 & 0 & 0 & 0 \\ 0 & 0 & 0 & 0 \\ 0 & 0 & 0 & 0 \\ 0 & 0 & 0 & 0\end{matrix} ] & ( 14 ) \\ B 81 = [ \begin{matrix}{λ}_{B 8} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 15 )\end{matrix}$$
sub-matrix A3 is a square matrix with 12 lines and 12 columns:
$$A 3 = [ \begin{matrix}B 10 & B 111 & B 121 \\ O & B 11 & O \\ 0 & O & B 12\end{matrix} ] \qquad ( 16 )$$
in Formula (16), B10, B111, B121, B11, B12 are nonzero matrices, O stands for zero matrix, B111 and B121 of the five nonzero matrices have only one nonzero element, the rest elements are all zero elements, and the five sub-matrices are:
$$\begin{matrix}B 10 = [ \begin{matrix}- ( {λ}_{B 10} + {λ}_{B 11} + {λ}_{B 12} + {λ}_{B 13} ) & {λ}_{B 10} & 0 & 0 \\ 0 & - ( {λ}_{C 29} + {λ}_{C 30} + {λ}_{C 31} ) & {λ}_{C 29} & {λ}_{C 30} \\ 0 & 0 & - {λ}_{F 22} & 0 \\ 0 & 0 & 0 & - {λ}_{F 23}\end{matrix} ] & ( 17 ) \\ B 11 = [ \begin{matrix}- ( {λ}_{C 32} + {λ}_{C 33} + {λ}_{C 34} + {λ}_{C 35} ) & {λ}_{C 32} & {λ}_{C 33} & {λ}_{C 34} \\ 0 & - {λ}_{F24} & 0 & 0 \\ 0 & 0 & - {λ}_{F 25} & 0 \\ 0 & 0 & 0 & - {λ}_{F 26}\end{matrix} ] & ( 18 ) \\ B 12 = [ \begin{matrix}- ( {λ}_{C 36} + {λ}_{C 37} + {λ}_{C 38} + {λ}_{C 39} ) & {λ}_{C 36} & {λ}_{C 37} & {λ}_{C 38} \\ 0 & - {λ}_{F 27} & 0 & 0 \\ 0 & 0 & - {λ}_{F 28} & 0 \\ 0 & 0 & 0 & - {λ}_{F 29}\end{matrix} ] & ( 19 ) \\ B 111 = [ \begin{matrix}{λ}_{B 11} & 0 & 0 & 0 \\ 0 & 0 & 0 & 0 \\ 0 & 0 & 0 & 0 \\ 0 & 0 & 0 & 0\end{matrix} ] & ( 20 ) \\ B 121 = [ \begin{matrix}{λ}_{B 12} & 0 & 0 & 0 \\ 0 & 0 & 0 & 0 \\ 0 & 0 & 0 & 0 \\ 0 & 0 & 0 & 0\end{matrix} ] & ( 21 )\end{matrix}$$
sub-matrix A4 is a square matrix with 19 lines and 19 columns:
$$A 4 = [ \begin{matrix}B 14 & B 151 & B 161 & B 171 \\ O & B 15 & O & O \\ O & O & B 16 & O \\ O & O & O & B 17\end{matrix} ] \qquad ( 22 )$$
in Formula (22), B14, B151, B161, B171, B15, B16, B17 are nonzero matrices, O stands for zero matrix, B151, B161 and B171 of the seven nonzero matrices have only one nonzero element, the rest elements are all zero elements, and the seven sub-matrices are:
$$\begin{matrix}B 14 = [ \begin{matrix}- ( {λ}_{B 14} + {λ}_{B 15} + {λ}_{B 16} + {λ}_{B 17} + {λ}_{B 18} ) & {λ}_{B 14} & 0 & 0 & 0 \\ 0 & - ( {λ}_{C 40} + {λ}_{C 41} + {λ}_{C 42} + {λ}_{C 43} ) & {λ}_{C 40} & {λ}_{C 41} & {λ}_{C 42} \\ 0 & 0 & - {λ}_{F 30} & 0 & 0 \\ 0 & 0 & 0 & - {λ}_{F 31} & 0 \\ 0 & 0 & 0 & 0 & - {λ}_{F 32}\end{matrix} ] & ( 23 ) \\ B 15 = [ \begin{matrix}- ( {λ}_{C 44} + {λ}_{C 45} + {λ}_{C 46} + {λ}_{C 47} + {λ}_{C 48} ) & {λ}_{C 44} & {λ}_{C 45} & {λ}_{C 46} & {λ}_{C 47} \\ 0 & - {λ}_{F 33} & 0 & 0 & 0 \\ 0 & 0 & - {λ}_{F 34} & 0 & 0 \\ 0 & 0 & 0 & - {λ}_{F 35} & 0 \\ 0 & 0 & 0 & 0 & - {λ}_{F 36}\end{matrix} ] & ( 24 ) \\ B 16 = [ \begin{matrix}- ( {λ}_{C 49} + {λ}_{C 50} + {λ}_{C 51} + {λ}_{C 52} ) & {λ}_{C 49} & {λ}_{C 50} & {λ}_{C 51} \\ 0 & - {λ}_{F 37} & 0 & 0 \\ 0 & 0 & - {λ}_{F 38} & 0 \\ 0 & 0 & 0 & - {λ}_{F 39}\end{matrix} ] & ( 25 ) \\ B 17 = [ \begin{matrix}- ( {λ}_{C 53} + {λ}_{C 54} + {λ}_{C 55} + {λ}_{C 56} + {λ}_{C 57} ) & {λ}_{C 53} & {λ}_{C 54} & {λ}_{C 55} & {λ}_{C 56} \\ 0 & - {λ}_{F 40} & 0 & 0 & 0 \\ 0 & 0 & - {λ}_{F 41} & 0 & 0 \\ 0 & 0 & 0 & - {λ}_{F 42} & 0 \\ 0 & 0 & 0 & 0 & - {λ}_{F 43}\end{matrix} ] & ( 26 ) \\ B 151 = [ \begin{matrix}{λ}_{B 15} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 27 ) \\ B 161 = [ \begin{matrix}{λ}_{B 16} & 0 & 0 & 0 \\ 0 & 0 & 0 & 0 \\ 0 & 0 & 0 & 0 \\ 0 & 0 & 0 & 0\end{matrix} ] & ( 28 ) \\ B 171 = [ \begin{matrix}{λ}_{B 17} & 0 & 0 & 0 & 0 \\ 0 & 0 & 0 & 0 & 0 \\ 0 & 0 & 0 & 0 & 0 \\ 0 & 0 & 0 & 0 & 0 \\ 0 & 0 & 0 & 0 & 0\end{matrix} ] & ( 29 )\end{matrix}$$
in the formula, λ_{A1}, λ_{A2}, λ_{A3}, λ_{A4}, λ_{A5}, λ_{B1}, λ_{B2}, λ_{B3}, λ_{B4}, λ_{B5}, λ_{B6}, λ_{B7}, λ_{B8}, λ_{B9}, λ_{B10}, λ_{B11}, λ_{B12}, λ_{B13}, λ_{B14}, λ_{B15}, λ_{B16}, λ_{B17}, λ_{B18}, λ_{C1}, λ_{C2}, λ_{C3}, λ_{C4}, λ_{C5}, λ_{C6}, λ_{C7}, λ_{C8}, λ_{C9}, λ_{C10}, λ_{C11}, λ_{C12}, λ_{C13}, λ_{C14}, λ_{C15}, λ_{C16}, λ_{C17}, λ_{C18}, λ_{C19}, λ_{C20}, λ_{C21}, λ_{C22}, λ_{C23}, λ_{C24}, λ_{C25}, λ_{C26}, λ_{C27}, λ_{C28}, λ_{C29}, λ_{C30}, λ_{C31}, λ_{C32}, λ_{C33}, λ_{C34}, λ_{C35}, λ_{C36}, λ_{C37}, λ_{C38}, λ_{C39}, λ_{C40}, λ_{C41}, λ_{C42}, λ_{C43}, λ_{C44}, λ_{C45}, λ_{C46}, λ_{C47}, λ_{C48}, λ_{C49}, λ_{C50}, λ_{C51}, λ_{C52}, λ_{C53}, λ_{C54}, λ_{C55}, λ_{C56}, λ_{C57}, λ_{F1}, λ_{F2}, λ_{F3}, λ_{F4}, λ_{F5}, λ_{F6}, λ_{F7}, λ_{F8}, λ_{F9}, λ_{F10}, λ_{F11}, λ_{F12}, λ_{F13}, λ_{F14}, λ_{F15}, λ_{F16}, λ_{F17}, λ_{F18}, λ_{F19}, λ_{F20}, λ_{F21}, λ_{F22}, λ_{F23}, λ_{F24}, λ_{F25}, λ_{F26}, λ_{F27}, λ_{F28}, λ_{F29}, λ_{F30}, λ_{F31}, λ_{F32}, λ_{F33}, λ_{F34}, λ_{F35}, λ_{F36}, λ_{F37}, λ_{F38}, λ_{F39}, λ_{F40}, λ_{F41}, λ_{F42}, λ_{F43} are state transition rates of a three-level Markov model;
by using Formula:
$$P ( t ) \cdot A = \frac{dP ( t )}{dt} \qquad ( 30 )$$
the probability matrix P(t) of the switched reluctance motor system in valid states is attained:
$$P ( t ) = [ \begin{matrix}{P}_{A 1} ( t ) \\ {P}_{A 2} ( t ) \\ {P}_{A 3} ( t ) \\ {P}_{A 4} ( t )\end{matrix} ] \qquad ( 31 )$$
in Formula (31), P_{A1}(t), P_{A2}(t), P_{A3}(t) and P_{A4} (t) denote valid-state probabilities in A1 submodel, A2 submodel, A3 submodel and A4 submodel, as shown in Formulae (32) to (35):
$$\begin{matrix}{P}_{A 1} ( t ) = [ \begin{matrix}exp ( - 4.81 t ) \\ 0.0686 exp ( - 299 t ) - 0.0686 exp ( - 4.81 t ) \\ 0.0202 exp ( - 2.95 t ) - 0.0206 exp ( - 2.99 t ) \\ 0.0128 exp ( - 1.54 t ) - 0.023 exp ( - 2.99 t ) + 0.0103 exp ( - 4.81 t ) \\ 0.0246 exp ( - 0.237 t ) - 0.06 exp ( - 2.99 t ) + 0.0374 exp ( - 4.81 t ) \\ 1.04 e - 4 exp ( - 2.95 t ) + 1.34 e - 5 exp ( - 4.43 t ) \\ 0.0516 exp ( - 2.99 t ) - 0.0525 exp ( - 2.95 t ) + 0.00134 exp ( - 2.01 t ) \\ 0.009 exp ( - 2.95 t ) - 0.009 exp ( - 2.99 t ) + 7.97 e - 4 exp ( - 4.04 t ) \\ 8.85 e - 4 exp ( - 3.67 t ) - 6.9 e - 4 exp ( - 2.99 t ) - 2.5 e - 4 exp ( - 4.81 t ) \\ 0.001 exp ( - 0.237 t ) - 0.013 exp ( - 2.99 t ) + 0.02 exp ( - 4.07 t ) \\ 3.48 e - 4 exp ( - 3.96 t ) - 1.37 e - 4 exp ( - 4.81 t ) \\ 0.145 exp ( - 3.19 t ) + 0.009 exp ( - 1.54 t ) - 0.147 exp ( - 2.99 t ) \\ 0.0103 exp ( - 3.64 t ) - 0.009 exp ( - 2.99 t ) - 0.002 exp ( - 4.81 t )\end{matrix} ] & ( 32 ) \\ {P}_{A 2} ( t ) = [ \begin{matrix}0.00659 exp ( - 3.08 t ) - 0.00659 exp ( 4.81 t ) \\ 0.006 exp ( - 2.96 t ) - 0.006 exp ( - 3.08 t ) + 4.43 e - 4 exp ( - 4.81 t ) \\ 0.001 exp ( - 3.04 t ) - 0.001 exp ( - 3.08 t ) \\ 0.002 exp ( - 0.404 t ) - 0.006 exp ( - 3.08 t ) + 0.004 exp ( - 4.81 t ) \\ 0.001 exp ( - 1.83 t ) - 0.002 exp ( - 3.08 t ) + 0.00108 exp ( - 4.81 t ) \\ 3.57 e - 5 exp ( - 2.96 t ) - 4.23 e - 5 exp ( - 3.08 t ) + 1.28 e - 5 exp ( - 4.27 t ) \\ 0.00976 exp ( - 3.5 t ) - 0.0342 exp ( - 3.08 t ) + 0.0253 exp ( - 2.96 t ) \\ 1.19 e - 4 exp ( - 3.04 t ) + 1.36 e - 5 exp ( - 4.27 t ) \\ 4.24 e - 4 exp ( - 3.74 t ) - 0.00441 exp ( - 3.08 t ) + 0.00405 exp ( - 3.04 t ) \\ 5.2 e - 4 exp ( - 3.04 t ) - 5.53 e - 4 exp ( - 3.08 t ) + 5.41 e - 5 exp ( - 4.14 t ) \\ 0.00186 exp ( - 3.55 t ) + 9.4 e - 5 exp ( - 0.404 t ) - 0.00159 exp ( - 3.08 t ) \\ 9.03 e - 5 exp ( - 3.74 t ) - 2.61 e - 5 exp ( - 4.81 t ) \\ 0.00523 exp ( - 3.43 t ) - 0.00472 exp ( - 3.08 t ) - 7.24 e - 4 exp ( - 4.81 t ) \\ 4.36 e - 4 exp ( - 3.96 t ) + 8.72 e - 5 exp ( - 1.83 ) - 3.66 e - 4 exp ( - 3.08 t ) \\ 4.88 e - 6 exp ( - 1.83 t ) + 2.58 e - 5 exp ( - 4.14 t ) \\ 0.00608 exp ( - 3.73 t ) + 0.00114 exp ( - 1.83 t ) - 0.00575 exp ( - 3.08 t ) \\ 8.7 e - 4 exp ( - 3.83 t ) - 7.88 e - 4 exp ( - 3.08 t ) - 2.53 e - 4 exp ( - 4.81 t ) \\ 6.48 e - 4 exp ( - 0.237 t ) - 7.37 e - 4 exp ( - 0.476 t ) + 1.84 e - 4 exp ( - 3.55 t )\end{matrix} ] & ( 33 ) \\ {P}_{A 3} ( t ) = [ \begin{matrix}0.575 exp ( - 0.476 t ) - 0.575 exp ( - 4.81 t ) \\ 0.284 exp ( - 0.237 t ) - 0.299 exp ( - 0.476 t ) + 0.015 exp ( - 4.81 t ) \\ 0.037 exp ( - 0.361 t ) - 0.038 exp ( - 0.476 t ) \\ 1.72 exp ( - 0.364 t ) - 1.77 exp ( - 0.476 t ) + 0.0445 exp ( - 4.81 t ) \\ 0.0216 exp ( - 0.237 t ) - 0.0248 exp ( - 0.476 t ) + 0.00547 exp ( - 3.24 t ) \\ 0.00115 exp ( - 0.361 t ) - 0.00121 exp ( - 0.476 t ) + 3.54 e - 4 exp ( - 4.39 t ) \\ 6.67 e - 5 exp ( - 0361 t ) - 7.04 e - 5 exp ( - 0.476 t ) + 3.48 e - 5 exp ( - 4.57 t ) \\ 0.00218 exp ( - 0.361 t ) - 0.00231 exp ( - 0.476 t ) + 5.35 e - 4 exp ( - 4.26 t ) \\ 0.0578 exp ( - 0.364 t ) + 0.00756 exp ( - 4.81 t ) + 0.0109 exp ( - 4.07 t ) \\ 0.0184 exp ( - 3.95 t ) - 0.117 exp ( - 0.476 t ) + 0.11 exp ( - 0.364 t ) \\ 0.00335 exp ( - 0.364 t ) - 0.00354 exp ( - 0.476 t ) + 8.03 e - 4 exp ( - 4.26 t ) \\ 0.00307 exp ( - 3.96 t ) - 1.45 e - 4 exp ( 1.82 t ) - 0.005 exp ( - 4.38 t )\end{matrix} ] & ( 34 ) \\ {P}_{A 4} ( t ) = [ \begin{matrix}3.93 exp ( - 4.38 t ) - 4.55 exp ( - 4.81 t ) \\ 0.0259 exp ( - 1.73 t ) + 0.159 exp ( - 4.81 t ) - 0.18 exp ( - 4.38 t ) \\ 0.002 exp ( - 1.82 t ) + 0.014 exp ( - 4.81 t ) - 0.017 exp ( - 4.38 t ) \\ 0.137 exp ( - 0.364 t ) + 1.28 exp ( - 4.81 t ) - 1.42 exp ( - 4.38 t ) \\ 0.056 exp ( - 1.72 t ) + 0.346 exp ( - 4.81 t ) - 0.402 exp ( - 4.38 t ) \\ 1.32 e - 4 exp ( - 1.73 t ) - 0.00299 exp ( - 3.96 t ) + 0.00497 exp ( - 4.38 t ) \\ 0.0248 exp ( - 1.73 t ) - 0.114 exp ( - 3.24 t ) + 0.236 exp ( - 4.38 t ) \\ 0.00367 exp ( - 1.73 t ) - 0.035 exp ( - 3.64 t ) - 0.0371 exp ( - 4.81 t ) \\ 5.47 e - 4 exp ( - 4.38 t ) - 3.88 e - 4 exp ( - 4.14 t ) \\ 0.00183 exp ( - 1.82 t ) - 0.0194 exp ( - 4.81 t ) + 0.0379 exp ( - 4.38 t ) \\ 0.00476 exp ( - 3.83 t ) - 0.00409 exp ( - 4.81 t ) + 0.00851 exp ( - 4.38 t ) \\ 0.0595 exp ( - 3.24 t ) - 0.102 exp ( - 4.81 t ) + 0.155 exp ( - 4.38 t ) \\ 0.0046 exp ( - 3.42 t ) - 0.00702 exp ( - 4.81 t ) + 0.0113 exp ( - 4.38 t ) \\ 0.0115 exp ( - 0.364 t ) - 0.0952 exp ( - 3.11 t ) + 0.257 exp ( - 4.38 t ) \\ 0.00405 exp ( - 1.72 t ) - 0.0315 exp ( - 4.81 t ) + 0.0535 exp ( - 4.38 t ) \\ 0.0103 exp ( - 3.64 t ) + 0.001 exp ( - 1.54 t ) - 0.009 exp ( - 2.99 t ) \\ 0.00607 exp ( - 4.38 t ) - 0.00308 exp ( - 3.63 t ) - 0.00332 exp ( - 4.8 t ) \\ 0.0547 exp ( - 1.72 t ) - 0.245 exp ( - 3.22 t ) + 0.51 exp ( - 4.38 t ) \\ 0.044 exp ( - 4.38 t ) - 0.0211 exp ( - 3.32 t ) - 0.027 exp ( - 4.81 t )\end{matrix} ] & ( 35 )\end{matrix}$$
in Formulae (32) to (35), exp denotes an exponential function, t denotes time, and A stands for a state transition matrix;
the sum of all elements of probability matrix P(t) in valid states is calculated with Formula (31) to obtain reliability function R(t) of the switched reluctance motor system:
$$R ( t ) = [ \begin{matrix}0.0018 exp ( - 3.96 t ) + 0.0184 exp ( - 3.95 t ) + 8.7 e - 4 exp ( - 3.83 t ) \\ - 0.004 exp ( - 3.83 t ) - 1.74 exp ( - 0.476 t ) + 0.332 exp ( - 0.237 t ) + 5.14 e \\ - 4 exp ( - 3.74 t ) - 0.0142 exp ( - 3.73 t ) + 8.85 e - 4 exp ( - 3.67 t ) \\ + 0.0029 exp ( - 1.83 t ) + 0.01 exp ( - 3.64 t ) - 0.035 exp ( - 3.64 t ) \\ + 0.004 exp ( - 1.82 t ) - 0.003 exp ( - 3.63 t ) - 0.011 exp ( - 3.55 t ) \\ + 0.0544 exp ( - 1.73 t ) - 0.026 exp ( - 3.44 t ) + 0.119 exp ( - 1.72 t ) \\ + 0.005 exp ( - 3.43 t ) - 0.0046 exp ( - 3.42 t ) - 0.0211 exp ( - 3.32 t ) \\ - 0.108 exp ( - 3.24 t ) - 0.0595 exp ( - 3.24 t ) + 0.00269 exp ( - 0.404 t ) \\ - 0.245 exp ( - 3.22 t ) + 0.145 exp ( - 3.19 t ) - 0.0952 exp ( - 3.11 t ) \\ - 0.0662 exp ( - 3.08 t ) + 0.024 exp ( - 1.54 t ) + 0.005 exp ( - 3.04 t ) \\ - 0.166 exp ( - 2.99 t ) + 0.0345 exp ( - 2.96 t ) - 0.0231 exp ( - 2.95 t ) \\ + 2.05 exp ( - 0.364 t ) + 0.04 exp ( - 0.36 t ) - 2.59 exp ( - 4.81 t ) \\ + 3.48 e - 5 exp ( - 4.57 t ) + 1.34 e - 5 exp ( - 4.43 t ) + 3.54 e - 4 exp ( - 4.39 t ) \\ + 3.3 exp ( - 4.38 t ) + 1.28 e - 5 exp ( - 4.27 t ) + 1.36 e - 5 exp ( - 4.27 t ) \\ + 0.0013 exp ( - 4.26 t ) - 3.08 e - 4 exp ( - 4.14 t ) + 0.01 exp ( - 4.07 t ) \\ + 0.023 exp ( - 4.07 t ) + 7.97 e - 4 exp ( - 4.04 ) + 0.001 exp ( - 2.01 t )\end{matrix} ] \qquad ( 36 )$$
from reliability function R(t), MTTF of the switched reluctance motor system is calculated:
$$MTIF = {\int }_{0}^{∞} R ( t ) dt \qquad ( 37 )$$
thereby, evaluation of switched reluctance motor system reliability is realized through quantitative analysis of three-level Markov model.
